(19) United States
(12) Patent Application Publication
(10) Pub. No.: US 2024/0363738 A1
(43) Pub. Date: Oct. 31, 2024

(54) SYSTEM AND METHOD FOR CONTROLLING QUANTUM PROCESSING ELEMENTS

(71) Applicant: Diraq Pty Ltd, Elizabeth Bay, New South Wales (AU)

(72) Inventors: Ingvild HANSEN, Elizabeth Bay (AU); Amanda Elizabeth SEEDHOUSE, Elizabeth Bay (AU); André Luiz SARAIVA DE OLIVEIRA, Elizabeth Bay (AU); Chih-Hwan Henry YANG, Elizabeth Bay (AU); Arne LAUCHT, Elizabeth Bay (AU); Andrew Steven DZURAK, Elizabeth Bay (AU)

(21) Appl. No.: 18/291,779

(22) PCT Filed: Jul. 29, 2022
(86) PCT No.: PCT/AU2022/050804

§ 371 Date: Jan. 24, 2024

(30) Foreign Application Priority Data
Jul. 30, 2021 (AU) 2021902356

(51) Int. Cl. H01L 29/66; B82Y 10/00; G06N 10/20; G06N 10/40; H01L 29/82

(52) U.S. Cl. CPC H01L 29/66977; B82Y 10/00; G06N 10/20; G06N 10/40; H01L 29/82

(57) ABSTRACT

The present disclosure is related to quantum processing systems and more particularly to systems and methods for controlling quantum processing elements. A method for controlling one or more qubits in a quantum processing system, the quantum processing system comprising a plurality of qubits. The method comprises generating an AC electromagnetic field, modulating the amplitude of the AC electromagnetic field to generate an amplitude modulated AC electromagnetic field, applying the amplitude modulated AC electromagnetic field to the quantum processing system, wherein in an idle mode the plurality of qubits are tuned to be on resonance with the amplitude modulated AC electromagnetic field, and individually controlling the Larmor frequency of the one or more qubits to change synchronously with the amplitude modulated AC electromagnetic field to perform an operation on the one or more qubits.

### CROSS REFERENCE TO RELATED APPLICATIONS

The present application is a National Stage entry of the International Application No. PCT/AU2022/050804, filed Jul. 29, 2022, which claims priority to the Australian Application Number 2021902356, filed Jul. 30, 2021, both of which are incorporated by reference in their entireties.

### TECHNICAL FIELD

Aspects of the present disclosure are related to quantum processing systems and more particularly to systems and methods for controlling quantum processing elements.

### BACKGROUND

Quantum computers and quantum simulators are poised to revolutionize many aspects of our modern society, from fundamental science and medical research to national security. The implications to defense of many of these applications, such as finding prime factors or encryption breaking, designing new materials from first-principles, artificial intelligence and machine learning will be considerable. Whilst a few applications are expected to be executable on medium-scale quantum computers (with 100-1000 qubits) that do not employ error correction protocols, some of the most disruptive algorithms, for example Shor's algorithm for prime factoring, will require a large-scale and fully fault-tolerant quantum computer with upwards of a million qubits.

However, before such large-scale quantum computers can be manufactured commercially, a number of hurdles need to be overcome. One such hurdle is control of qubits (the basic unit of quantum information control). To date, several techniques have been proposed to control the states of qubits, but these techniques either cannot be effectively scaled-up or result in faster decoherence.

Accordingly, there exists a need for a scalable qubit control system that can simultaneously control multiple qubits while not adversely affecting the operation of the qubits.

### SUMMARY

According to a first aspect of the present disclosure there is provided a method for controlling one or more qubits in a quantum processing system, the quantum processing system comprising a plurality of qubits, the method comprising: generating an AC electromagnetic field: modulating the amplitude of the AC electromagnetic field to generate an amplitude modulated AC electromagnetic field: applying the amplitude modulated AC electromagnetic field to the quantum processing system, wherein in an idle mode the plurality of qubits are tuned to be on resonance with the amplitude modulated AC electromagnetic field; and individually controlling the Larmor frequency of the one or more qubits to change synchronously with the amplitude modulated AC electromagnetic field to perform an operation on the one or more qubits.

According to a second aspect of the present disclosure there is provided a method for controlling one or more qubits in a quantum processing system, the quantum processing system comprising a plurality of qubits, the method comprising: applying an always on AC electromagnetic field to the quantum processing system, wherein in an idle mode the plurality of qubits are tuned to be on resonance with the AC electromagnetic field; and performing an initialization, qubit quantum gate, or readout operation on the one or more qubits by leveraging Pauli's exclusion principle while the AC electromagnetic field is applied to the quantum processing system.

Further aspects of the present invention and further embodiments of the aspects described in the preceding paragraphs will become apparent from the following description, given by way of example and with reference to the accompanying drawings.

### BRIEF DESCRIPTION OF DRAWINGS

Features and advantages of the present invention will become apparent from the following description of embodiments thereof, by way of example only, with reference to the accompanying drawings, in which:

FIG. 1A shows a previously known qubit control method using spin qubit resonance for a single qubit.

FIG. 1B shows a time trace as a function of frequency of four qubits shown in FIG. 1A.

FIG. 2A shows a previously known spin qubit control method using a global field.

FIG. 2B shows operations performed on qubits in a global field of FIG. 2A.

FIG. 3A shows a schematic of the dressed qubit global control according to aspects of the present invention.

FIG. 3B shows operations performed on qubits in a global field of FIG. 3A.

FIG. 4 shows a Bloch sphere representation of a transformation of a frame resulting from the transformation of a bare spin qubit frame into a dressed frame via Hadamard transformation.

FIGS. 5A-B show energy diagrams as a function of potential detuning ¿ for no difference in Zeeman energies (Δv₁=Δv₂=0), and the driving frequency hitting the centre of the Zeeman energy differences (Δv₁=−Δv₂), respectively. FIG. 5C shows the singlet state in the (0,2) configuration |S(0,2) [symbol] with an energy axis focused near the spin conserving transition. FIG. 5D shows the initialization sequence with time on the vertical axis, and detuning on the horizontal axis. FIG. 5E shows state probability as a function of ramp time.

FIG. 6A-B shows two methods of single qubit control, where the frequency detuning is plotted against time for both methods. FIG. 6A shows a frequency-shift keying method and FIG. 6B shows an FM resonance method.

FIG. 7 shows transition of a SWAP gate regime into a CPHASE regime determined by the angle of precession axis θ, measured from the z-axis of the Bloch sphere for a two-qubit gate.

FIGS. 8A-F show a comparison of the resilience to detuning noise between the dressed (FIG. 8A, 8C, 8D) and the SMART method (FIG. 8B, 8E, 8F).

FIGS. 9A-F shows the geometric formalism that describes the noise-cancelling properties of the dressed technique (FIGS. 9A, 9C, 9E) and the SMART technique (FIGS. 9B, 9D, 9F), respectively.

FIGS. 10(a)-(h) show rotation axis parameters for the two axes, v and w, including, for the SMART qubit method, showing ϕᵣ in FIGS. 10(a)-10(b), θᵣ in FIGS. 10(c)-10(d) and η in FIGS. 10(e)-10(f). In FIGS. 10(g)-10(h) the two axes are shown on a Bloch sphere where the relative angle between them is highlighted.

FIGS. 11(a)-(f) show qubit gate fidelities for different frequency detuning and amplitude noise levels for bare identity, dressed identity, SMART identity, including showing the identity gate fidelities for the bare, dressed spin qubit, and an \sqrt{X} gate operation in FIGS. 11(a)-11(c), and the SMART qubit method identity, \sqrt{X} gate operation and \sqrt{Y} gate operation in FIGS. 11(d)-(f).

FIGS. 12(a)-(f) show two qubit gate fidelities for different frequency detuning and amplitude noise levels, including showing the dressed and SMART \sqrt{SWAP} in FIGS. 12 (a)-(b) respectively, the dressed and SMART CNOT gates in FIGS. 12(c)-(d), and the dressed and SMART CNOTx gates in FIGS. 12(e)-(f).

FIGS. 13(a)-(b) show convergence of the amplitudes of two harmonics used for Stark shift control in the SMART technique for an \sqrt{X} gate and a \sqrt{Y} gate, respectively.

FIGS. 14(a)-(d) show a model used to generate the 2D maps in FIGS. 11-13 with Gaussian noise, including showing, in FIGS. 14(a)-(c), three different noise levels are illustrated with the fixed noise map and a 2D Gaussian which are multiplied to generate the three stars shown in FIG. 14(d).

FIGS. 15(a)-(h) show two-qubit initialization of qubits operated under the SMART technique, including showing an energy diagram in FIG. 15(a), a ramp sequence where the ramp is centered about the mw minimum in FIG. 15(b), the resulting state probability where a S(1,1) is initialised from S(0,2) in FIGS. 15(c) and 15(d), and the same as for FIGS. 15(a)-(d), but with the ramp centered about the mw maximum, in FIGS. 15(e)-(h).

FIG. 16 shows two qubit initialization for the dressed protocol, showing state probability where a S(1,1) is initialised from S(0,2).

FIGS. 17(a)-(d) show a device image, basis transformation and qubit readout window; including showing a false-colored scanning electron microscopy (SEM) image of an identical device in FIG. 17(a), a cross-section of the device from the dashed line in FIG. 17(a) in FIG. 17(b), the basis transformation in FIG. 17(c), and the qubit stability diagram used for readout in FIG. 17(d).

FIGS. 18(a)-(e) show a coherence time comparison between bare qubits and qubits operated in the dressed and SMART protocols, including a Ramsey-like experiment with wait time on the y-axis and modulation period on the x-axis in FIG. 18, the decay rate fitted and compared with the zeroth order Bessel function in FIG. 18(b), a comparison of the coherence data for the bare, dressed and SMART techniques respectively in FIGS. 18(c)-(e), and the mw pulse sequences for all three cases in FIG. 18(f).

FIGS. 19(a)-(d) show Stark shift data, including the Stark shift resulting from ramping gate G2 resulting in a Stark shift magnitude of −55.13 MHz/V in FIGS. 19(a)-(b), and the Stark shift from gate G1 with a magnitude of −124.71 MHz/V in FIGS. 19(c)-(d).

FIGS. 20(a)-(h) show the process tomography results in FIGS. 20(a)-(b) for the gates \sqrt{X}, \sqrt{Y} for dressed qubits with FM resonance control, in FIGS. 20(c)-(d) the gates \sqrt{X}, \sqrt{Y} for SMART qubits using cosine modulation, and in FIGS. 20(e)-(h) the gates \sqrt{V}, \sqrt{W}, \sqrt{X} and \sqrt{Y} for SMART qubits with sine modulation.

FIGS. 21(a)-(e) show results for randomized benchmarking for both the SMART qubit and dressed qubit, including the noise implementation and the respective pulse sequences in FIG. 21(a), randomized benchmarking data for a dressed qubit with no added noise in FIG. 21(b), the randomized benchmarking data with σ=20 kHz white, quasi-static Gaussian noise added on G2C in FIG. 21(c), and the same for the sine modulated SMART qubit in FIGS. 21(d) and 21(e).

FIGS. 22(a)-(f) show the results of testing a modulation technique that combines modulation harmonics, including showing different driving fields generated by combinations of the first and third harmonic of a sinusoid where driving fields with different properties appear for the modulated driving field for θ=−0.67545 radians in FIG. 22(a), the corresponding modulation shape in FIG. 22(d), experimental and simulated Ramsey data where the wait time is fixed at 400 us and T_{mod} equals 40 μs, in FIG. 22(b), further Ramsey data recorded for a range of amplitudes in FIG. 22(e), and the simulated data in FIGS. 22(c) and 22(f).

FIG. 23 is a flowchart illustrating an example method using the dressed technique.

FIG. 24 is a flowchart illustrating an example method using the SMART technique.

### DETAILED DESCRIPTION

Reference to any prior art in the specification is not an acknowledgment or suggestion that this prior art forms part of the common general knowledge in any jurisdiction or that this prior art could reasonably be expected to be understood, regarded as relevant, and/or combined with other pieces of prior art by a skilled person in the art.

### Overview

One type of quantum computing system is based on the spin states of individual quantum processing elements, where the quantum processing elements may be electron spins, hole spins, or nuclear spins localized in a semiconductor chip. These electron, hole and/or nuclear spins are confined either in gate-defined quantum dots or on donor or acceptor atoms that are positioned in a semiconductor substrate, and are referred to as quantum bits or qubits.

While quantum dots themselves are readily scalable, to initialize, control and readout quantum states of the qubits, it is generally necessary to connect these qubits to other electronic devices, such as electron reservoirs, single electron transistors and microwave antennae. These electronic devices are often not as readily scalable as the quantum dots themselves, requiring routing of currents from various sources in the periphery of the quantum device. As the number of these electronic devices grows, the creation of non-intercepting vias for the currents becomes increasingly challenging.

A building block for any large-scale quantum computer is a quantum gate—i.e., a basic quantum operation acting on one or two qubits. Examples of quantum gates include identity gates. Pauli gates, controlled gates, phase shift gates, SWAP gates, Toffoli gates, etc. Manipulating spin-based qubits in semiconductors, in particular performing fast operations on the spin states of qubits, is an important avenue for constructing a quantum gate. In particular, fast, individually addressable qubit operations (such as unitary transformations, quantum measurements, and initialization) are essential for scalable architectures.

To date there are two main means for manipulating/controlling the spin state of a qubit to perform such gate functions: magnetic control and electrical control. In magnetic control, either an on-chip generated or off-chip externally generated (or global) magnetic field is applied to a quantum chip to drive/control the qubits. In particular, qubit control can be realized by introducing an alternating magnetic field in a direction perpendicular to an applied DC magnetic field. This is generally done by running an AC current through on-chip antenna electrodes close to the qubits. The AC current generates an alternating magnetic field. When the frequency of this field matches the resonance frequency of the qubit, the spin qubit begins to rotate as a function of time. These oscillations are called Rabi oscillations and they form the basis of single qubit rotations and control.

The integration of multiple quantum dots in a qubit array requires the creation of a dense arrangement of electrodes for confining multiple electrons in a two-dimensional lattice. This creates difficulties to integrate other on-chip devices that might be necessary to control, and readout said qubits. Integrating a broadband microwave antenna for spin resonance (which is one possible strategy for spin control) creates important constraints on a planar geometry, taking up a considerable region of the chip and is only effective at driving spin rotations if positioned very close to a particular spin in the system (typically no more than a few hundreds of nanometers).

Although magnetic control allows for high-fidelity single and two-qubit gates in silicon-based qubits, the technical complexity of generating local oscillating magnetic fields on the nanometer scale (the scale at which quantum dots are often fabricated) remains a significant hurdle for the future scalability of magnetic control. Further, the local oscillating currents often generate heat in the quantum computing chip, which is incompatible with the cryogenic environment necessary for qubit coherence. In the case in which the magnetic field is generated by an on-chip antenna, the antenna takes up precious real estate on the quantum computing chip. These difficulties provide motivation to manipulate spins electrically.

Another spin control technique that creates challenging constraints in device design is the electrically driven spin resonance (EDSR) technique that uses an integrated magnetic material-typically using on-chip micro-magnets. The size of these materials and the geometry required to obtain a desirable magnetic field gradient, limits its applicability only to small sets of quantum dots, with an unclear pathway for integrating this technology in a large two-dimensional array of quantum dots.

Selective control of individual spin qubits becomes limiting if the control mechanism uses microwave pulsed spin resonance and addresses each spin by their unique Larmor frequency. Generally speaking, the states of a spin are separated energetically by an externally applied DC magnetic field \vec{B₀}, and the up and down spin states (parallel and antiparallel to \vec{B₀}) are the |0 [symbol] and |1 [symbol] states. Any superposition of the up and down states, when observed from a laboratory frame, processes around the axis defined by \vec{B₀} with a frequency set by f_{Q}=g μ_{B}|\vec{B₀}|/h, which is called the qubit Larmor frequency or precession frequency. The Larmor frequency of a spin in a semiconductor device is determined by the microscopic environment that surrounds the spin, which sets the effective value of g. For the case of spin qubits in isotopically enriched silicon (²⁸Si), the spin-orbit interaction is the main mechanism that results in variable qubit Larmor frequencies.

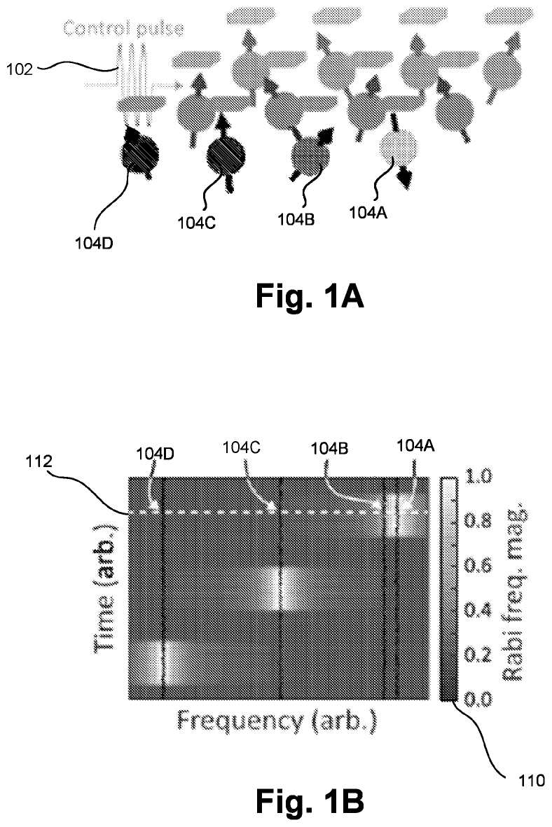

FIG. 1A schematically shows this method of spin qubit resonance for single qubit control. In FIG. 1A, a microwave pulse 102 is applied to an array of qubits 104. Since each of the qubits 104 in the qubit array have a unique Larmor frequency, the frequency of the microwave pulse 102 may be chosen such that it affects a target qubit, e.g., qubit 104A.

In this example, microwave pulse 102 causes only target qubit 104A to be “on resonance”. As such, qubit 104A may rotate between the spin up and spin down states as a function of time. These oscillations are called Rabi oscillations and they form the basis of single qubit rotations and control. The other qubits are “off-resonance”, simply precessing around the axis defined by \vec{B₀} with their unique Larmor frequencies.

The microwave control pulse 102 that is targeting qubit 104A simultaneously acts on all qubits of the qubit array. Because of this, unintentional interactions between the microwave field and other qubits in the qubit array are possible. In this example, qubit 104B has a Larmor frequency close to target qubit 104A, which may result in unwanted rotations in qubit 104B.

FIG. 1B shows a time trace as a function of frequency of four qubits shown in FIG. 1A. Frequency is plotted on the x-axis whereas time is plotted on the y-axis. The spin Larmor frequencies of four qubits 104A, 104B, 104C and 104D are represented by the vertical solid lines in the plot. The condition for a given qubit to be on resonance is represented as a gradient map 110 shows the magnitude of the Rabi oscillation resulting from the microwave control pulse 102, assuming the initial state was either spin up or spin down.

This amplitude is maximum when the microwave pulse 102 matches the qubit frequency, and decays as the qubit detunes in a range set by the Rabi frequency. The control pulses of qubits 104C and 104D are performed with no unwanted rotations, but as qubits 104A and 104B are similar in frequency, when one qubit is targeted, there is significant off-resonant driving on the neighboring qubit. The white dashed line 112 shows the time instance that FIG. 1A represents.

In other examples the microwave pulse frequency may be chosen to target any of the other qubits in the qubit array 104.

To achieve spin resonance in large scale qubit arrays by selectively driving each individual Larmor frequency, each qubit's Larmor frequency should be separated by several times the Rabi frequency in order to avoid errors (such as the unwanted rotations shown with respect to FIGS. 1A and 1B) that can degrade the quality of fault tolerant operations. The use of pulse shaping or engineering different qubit Larmor frequencies with a magnetic field gradient introduced by a micro-magnet may help avoid the aforementioned errors. However, there remains a significant hurdle to individually address qubits in systems on the order of hundreds or thousands of qubits with limited on-chip space.

A potential solution is to move away from on-chip devices and to drive spin resonances by alternating electromagnetic fields generated remotely. Examples of potential ways to create these fields remotely could include the use of dielectric resonators, magnetic resonators mounted on a different chip next to the qubit chip, three-dimensional cavities, etc.

The main difficulty with this strategy is to perform control of individualized qubits in an addressable fashion, i.e., by individually controlling the quantum state of each of the qubits in the array on demand. One strategy for achieving this individualized control uses the spin-orbit effect caused by the silicon/oxide interface. In particular, this method locally controls the spin-orbit interactions by applying electric fields with gate electrodes, in order to dynamically control the value of the spin resonance frequency.

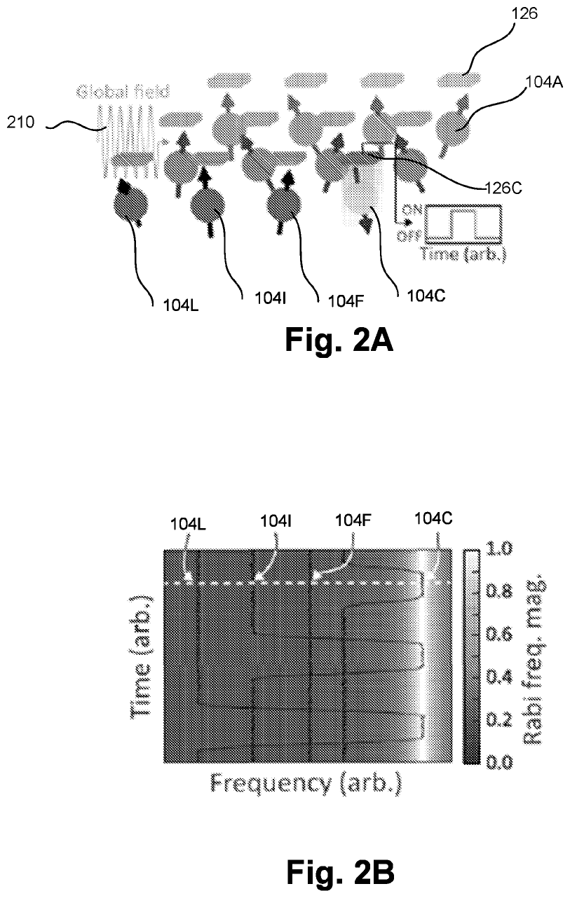

FIG. 2A schematically shows an example spin qubit control method using a global field. In this example, a global electromagnetic field 210 is applied to an array of qubits 104. The global electromagnetic field 210 is always on.

Further, the arrangement shown in FIG. 2A includes electrodes 126. The electrodes 126 are responsible for confining electrons in quantum dots. These electrodes may also be used for achieving shifts in qubit resonant frequency within a certain range. In this control technique, the qubits 104 are in an idle state and out of resonance with the global field 210 during normal operation. That is, qubits are simply precessing about \vec{B₀} during normal operation. To perform qubit operations, the qubits may be individually brought into resonance with the global field 210 by some method that locally controls the qubit frequency. This can be performed, for example, by electrically controlling the frequency shift caused by the hyperfine or spin-orbit interactions using a gate electrode, shifting the qubit by locally controlling the g-factor, or a combination of the two

To operate one of the qubits, e.g., qubit 104C, the voltages on the electrode (e.g., 126C) surrounding that particular qubit are then changed to change the Stark shift of the qubit 104C, thus changing its g-factor. The change in g-factor is chosen to bring the qubit into resonance with the global field 210, allowing for rotations to occur.

This method removes the issue of having individual resonance frequencies for each qubit, reducing crosstalk effects. FIG. 2B shows three rotations performed on qubits in such an off-resonance global field. When the controlled rotations are performed the individual qubits are brought into resonance, matching the global field frequency.

The limitation of this method is the typical noise found in these qubit which requires the qubits to be able to be detuned further than the global field linewidth. This strategy may be feasible in an idealized qubit device with no electric noise and no nuclear spins. In the presence of spins of ²⁹Si nuclei or in the presence of electric noise, the qubit frequency shifts over time. This means that two effects limit the precision of the spin control in this scenario—the shifts in frequency of the qubit will cause it to under-rotate or over-rotate with regard to the rotating frame, causing errors in the qubits phase compromising the precision with which a qubit can be brought onto resonance with the external AC electromagnetic field.

Moreover, the errors induced by these microscopic sources of noise are relatively slow. Accordingly, if at a certain time step a specific qubit undergoes a phase error, it is probable that in the following time step the same error will occur. This is a problem for quantum error correction schemes that assume that errors only occur in a sparse, uncorrelated fashion across the qubit array.

Aspects of the present disclosure address these issues by proposing a new technique for controlling individual qubits using an ‘always on’ global electromagnetic field. In particular, aspects of the present disclosure provide a technique for controlling qubits where the qubits are tuned so that they are constantly being driven or “on resonance” with this always on global electromagnetic field. This creates dressed qubits—i.e., qubits that couple spins of a qubit array with the photons of the global electromagnetic field. Dressed qubits retain quantum information much longer than standard spin qubits. Aspects of the present disclosure provide a new, universal and scalable control technique based on dressed qubits—which is referred to as a dressed technique in this disclosure. In the dressed technique, control operations such as readout, initialization, and gate operations are performed on the qubits by leveraging Pauli's exclusion principle, while the global electromagnetic field is on. Further, readout and initialization can be carried out on the dressed qubits while they are on resonance with the global electromagnetic field. To perform gate operations, one or more qubits may be brought off-resonance with the global electromagnetic field to perform the gate operations and then brought back on resonance with the global electromagnetic field once the operations have been performed.

Moreover, aspects of the present disclosure provide two approaches for engineering the external AC global field. The first approach uses an external microwave field with a constant amplitude. The second approach uses a sinusoidally modulated microwave amplitude which is engineered to circumvent noise of larger amplitudes and/or noise transversal to the quantization axis. This second approach provides superior noise resilience. In this disclosure, qubit operation using the second approach (i.e., an amplitude modulated sinusoidal microwave) is referred to as a SMART (Sinusoidally Modulated, Always Rotating and Tailored) technique. Further, when this SMART technique is applied to qubits, they are referred to as SMART qubits in this disclosure. This technique is used to find analytical forms of the global driving field that maximize the robustness of the qubits against quasi-static noise.

The SMART technique may, in principle, also be used in other qubit technologies besides spin qubits in quantum dots. The example of the present disclosure focuses on spins in silicon quantum dots, but the mathematical model behind the SMART technique is readily transferrable to most other two-level systems, e.g., donor qubits and acceptor qubits, color centers, and superconducting qubits.

In this disclosure, the dressed and SMART techniques are described with respect to a global electromagnetic field—that is, a field globally applied to a quantum processing system by an off-chip electromagnetic source. However, it will be appreciated that this global electromagnetic field can be replaced by a locally applied electromagnetic field—that is, an electromagnetic field that is applied locally to each qubit in a qubit processing system, such that the qubits are on resonance with the locally applied AC electromagnetic field. The electromagnetic field may be applied locally using one or more additional structures on the quantum processing system or by using one or more gate electrodes. In some examples, instead of applying the electromagnetic field locally to all the qubits in the quantum processing system, it may be applied to a subset of qubits of the quantum processing system.

Both the dressed and SMART techniques simplify the implementation of a large scale qubit system by: operating all qubits at the same microwave frequency, but making them individually addressable: avoiding effects of jitter between electrical control systems: creating the possibility of using off-chip intense electromagnetic microwave radiation sources for driving the qubits: creating qubit states that are dynamically decoupled from various microscopic sources of noise; and leading to qubits with errors that are less frequent, less correlated in time and potentially less correlated spatially.

These and other advantages of the presently disclosed qubit device and control/operation techniques will be described in detail in the following sections.

### Example Quantum Processing System in the Dressed Protocol

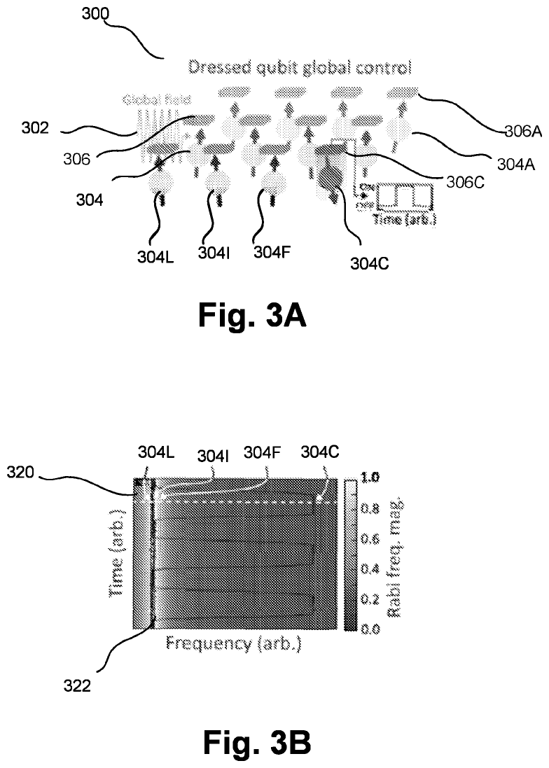

FIG. 3A shows a schematic 300 of the dressed qubit global control method according to the present disclosure. The schematic 300 shows a 3×4 array of spin qubits 304. Each spin qubit 304 may have an associated gate electrode 306 that in the case of a quantum dot system can be used to isolate electrons under the gate electrode 306 to form the qubits 304. In some examples, the spin qubits 304 may be formed in a silicon substrate (not shown) and more particularly under an interface formed between the silicon substrate and a dielectric material (not shown) such as silicon dioxide.

An AC global electromagnetic field 302 is applied to the qubit array, such that all the qubits 304 are tuned to be on resonance with the global field 302. That is, the qubits are driven by the global field 302 in their idle state. In some examples, the global field 302 is a constant amplitude sinusoidal driving field. In some examples the global field 302 may be a magnetic field, and in other examples the global field 302 may be an electric field. The constant amplitude global field 302 can be the result of a constant power applied to an external driving microwave system such as a broadband antenna, cavity or any type of resonator. In this case, the external driving microwave system can have arbitrarily large quality factors (arbitrarily small bandwidths) since the amplitude is constant throughout the complete operation of the quantum processor, including initialization, all control steps and readout.

The array of spin qubits 304 are set to have Larmor frequencies within a predefined threshold range. In particular, the qubits can be set to have similar Larmor frequencies, which are used for the global driving. In one embodiment, all qubits 304 in the qubit array are set to be perfectly on resonance with the external global field 302 oscillating at frequency f_{mw}. This may be done by calibrating the qubit resonance frequencies using the frequency shift caused by spin-orbit coupling, which can be controlled by the voltage of each individual top gate 306 and the global DC magnetic field acting on all the qubits 304. The direction of the external DC magnetic field in relation to the crystal lattice determines how the spin-orbit coupling affects the qubit frequency.

The electric shift of the qubit resonant frequency is called Stark shift. In reality, some offsets between the qubit Larmor frequencies can be tolerated as long as they are small in comparison to the Rabi frequency Ω_{R} that results from the externally applied AC electromagnetic driving microwave field. This is demonstrated in the Hamiltonian Hₚ below where the σ_{z} direction energy (Ω_{R}) is dominating to ensure the noise decoupling effects of the dressed technique are realized.

$${H}_{ρ} = {Ω}_{R} {σ}_{z} + ( {f}_{Q} - {f}_{MW} ) {σ}_{x}$$

where Ω_{R} is the Rabi frequency, σ_{z}, σₓ are two of the Pauli matrices, f_{Q} is the qubit frequency and f_{mw} is the driving magnetic field frequency.

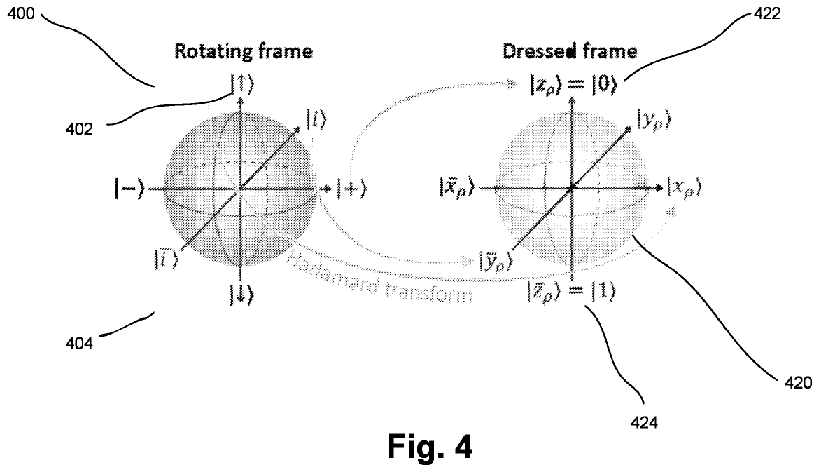

The dressed qubit system is described best in the Hadamard frame, which is the bare spin qubit frame transformed by the Hadamard operator as shown in FIG. 4. In particular, this figure shows a Bloch sphere representation of a rotating frame (i.e., a traditional spin qubit) 400 with a spin quantization axis along |↑ [symbol] . A bloch sphere is a geometrical representation of the state space of a qubit. The Bloch sphere is a unit 2-sphere, with antipodal points corresponding to a pair of mutually orthogonal state vectors.

The north and south poles of the Bloch sphere 400 are typically chosen to correspond to standard basis vectors, which in the context of spin qubits corresponds to the logical qubit state |0 [symbol] (or spin-up state |↑) [symbol] 402 and logical qubit state |1 [symbol] (or spin-down state |4 [symbol] ) 404. Points on the surface of the sphere correspond to states of the system. In this example, the surface of the sphere depicts the superposition states |+ [symbol] , |− [symbol] , |i [symbol] , |l̅ [symbol] . The operation of a qubit requires rotation of the qubits on the sphere between the |0 [symbol] and |1 [symbol] states.

To transform into the dressed frame, the constant amplitude global field 302 is applied to the spin qubit. The global field 302 changes the quantization axis to be along the |+ [symbol] , |− [symbol] axis. The dressed qubits are therefore defined as the superposition states |zₚ [symbol] =(1/\sqrt{2}) (|↓ [symbol] +|↑ [symbol] ) and |Z̅ₚ̅ [symbol] =(1/\sqrt{2}) (|↓>−|↑ [symbol] ). FIG. 4 illustrates a Bloch sphere representation of the dressed frame 420 with the qubit states defined as |0 [symbol] =|zₚ [symbol] (422) and |1 [symbol] =|Z̅ₚ [symbol] (424).

The energy difference between the logical states of the dressed qubit is determined by the Rabi frequency Ω_{R}, and the detuning of the driving global field 302 from the qubit frequency determines the qubit rotations, Δv=f_{q}−f_{mw}. This frequency detuning Δv is an intra-dot detuning and represents the detuning from the Larmor frequency for a given qubit.

Returning to FIG. 3A in order to control qubit 304C, the Larmor frequency of the qubit 304C can be shifted by applying voltages to gate electrode 306C. In some examples, the Larmor frequency of the qubit 304C can be shifted by applying voltages to a subset of gate electrodes 306. This affects the detuning between the qubit frequency and the frequency of the global field 302, thus bringing qubit 304C off-resonance and leading to x rotations of the qubits in the dressed frame.

FIG. 3B shows three controlled rotations performed in an on resonance global field with time on the y-axis and frequency on the x-axis. The Larmor frequency of each of the qubits 304 in qubit array are similar and represented by the vertical line 322 in the plot. The white dashed line 320 represents the time instance that FIG. 3A represents.

A similar transformation can be done on two-qubit spin states. For example, in a double quantum dot. A double quantum dot includes two quantum dots—a left quantum dot and a right quantum dot, each with one or more electrons, constructed side-by-side and tuned so that they are tunnel coupled.

Aspects of the present disclosure can perform similar transformations in such double quantum dots that have (N, M) charge occupation in the left or right quantum dot, where N, M are integers. In some example N=M and in other example N≠M.

In the example of two qubits each confined electrostatically in a quantum dot, singlet-triplet qubit states arise from the two-qubit interactions. Singlet states have a total spin quantum number S=0 and a triplet state has a total spin quantum number S=1. For example, the doubly occupied quantum dot, denoted |S(0,2) [symbol] is a low energy singlet state. In the case of the traditional spin qubit (not dressed), the other four levels are the single occupied, two-spin systems |↑↑ [symbol] , |↑↓ [symbol] , |↓↑ [symbol] , |↓↓ [symbol] . The eigenstates in the dressed singlet-triplet picture are {|S(0,2) [symbol] , |T_{+,p} [symbol] , |S(1,1) [symbol] , |T_{0,p} [symbol] , |T_{-,p} [symbol] }—this is the dressed five-level system.

Moreover, in a double quantum dot, each quantum dot has a respective qubit frequency, f_{Q,1} and f_{Q,2}. Thus, each quantum dot has a respective intra-dot frequency detuning Δv₁=f_{Q,1}−f_{mw} and Δv₂=f_{Q,2}−f_{MW}.

In a double quantum dot system there is also a second type of detuning ∈ that is the energy detuning between the two quantum dots, i.e., an inter-dot detuning. Both these types of detuning Δv and ∈ are used in this disclosure.

### Initialization and Readout

Before any gate operations can be performed on qubits, the qubits 304 need to be initialized in the proper spin state for the operation. For example, if a two-qubit gate operation is to be performed, the two qubits involved in the gate operation need to be initialized in the correct spin states before the gate operation can be performed. As the qubits 304 in a qubit array of the present disclosure are driven continuously by the external global field 302, initialization and readout can be achieved using Pauli spin blockade. The Pauli spin blockade leverages the principle of the Pauli Exclusion Principle between spins, which states no two fermions (particles with half-integer spin) can exist in the same quantum state.

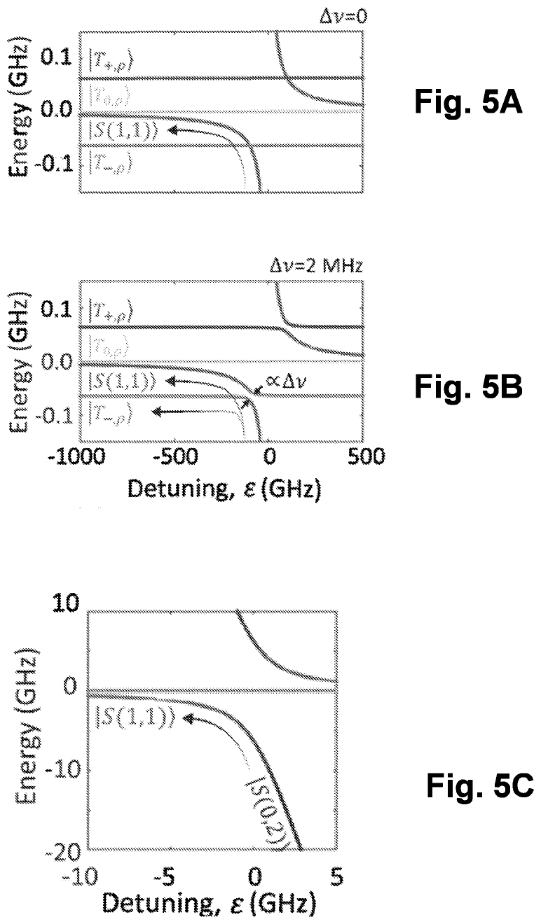

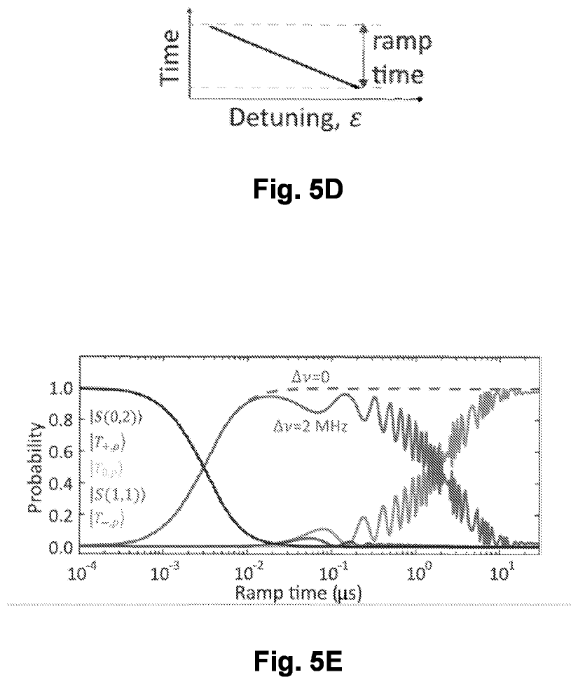

FIGS. 5A-5D show the initialization process for initializing double quantum dots with singlet-triplet qubits, including the probability of initialising particular states depending on system parameters. Energy dependent tunneling to a reservoir would be compromised by the fact that the electron spin is driven continuously, i.e., the driving microwave field is not turned off for the readout step. This allows for the readout of some processing elements while the other elements remain operational.

It is important to note that the Pauli blockade will isolate singlet states (e.g., |S(0,2) [symbol] , |S(1,1)) [symbol] . Singlet states have zero total spin and are invariant under rotations. Therefore, singlet states are independent of the choice of basis (frame) for describing spins. Singlet states are also immune to the external global field 302. This allows for pairwise readout and initialization in an isolated double dot system without the need for a nearby reservoir of electrons.

The behavior of each eigenenergy in the dressed five-level system is investigated as a function of the detuning ∈ between the two quantum dots. This is shown in FIGS. 5A-C. In particular, FIG. 5A shows an energy diagram as a function of potential detuning when there is no difference in Zeeman energies between the two quantum dots (i.e., when Δv₁=Δv₂=0), and FIG. 5B shows an energy diagram as a function of potential detuning when the driving frequency hits the center of the Zeeman energy differences (i.e., when Δv₁=−Δv₂. The colors of the lines show the contributions of each state. The dark blue shows the |S(0,2) [symbol] , blue is |S(1,1) [symbol] yellow is |T_{0,p} [symbol] brown is |T_{+,p} [symbol] and orange is |T_{-,p} [symbol] The black arrows show the path of initialization, either crossing the anti-crossing (in both FIGS. 5A and 5B) or avoiding it (only in FIG. 5B). FIG. 5C shows the singlet state in the (0,2) configuration |S(0,2) [symbol] with an energy axis focused near the spin conserving transition. The initialization sequence is shown in FIG. 5D with time on the vertical axis, and detuning on the horizontal. For each initialization, detuning ∈ is ramped for a particular ramp time at a constant rate from a positive to a negative energy-see FIG. 5D.

To start with, the case where energy detuning between the two dots e is ramped to transfer |S(0,2) [symbol] to |S(1,1) [symbol] is considered. In one example the qubit frequency detuning may be such that there is no difference in the Zeeman energies between the states of the two quantum dots (i.e., Δv₁=Δv₂=0). In this case there is no coupling term, which is demonstrated in FIG. 5A with an absence of an anti-crossing between |S(1,1) [symbol] and T_{-,p} [symbol] , allowing for a smooth transition from |S(0,2) [symbol] to |S(1,1) [symbol] .

The transition into |S(1,1) [symbol] is dependent on how fast detuning ∈ changes when ramping through the |S(0,2) [symbol] to |S(1,1) [symbol] anticrossing. The inverse of the tunnel coupling between the quantum dots sets the time scale for the ramp time. If the ramp time is significantly fast enough, |S(0,2) [symbol] diabatically crosses the energy anti-crossing, remaining at |S(0,2) [symbol] .

As the ramp time increases, the probability of preparing |S(1,1) [symbol] via an adiabatic crossing is increased. The probability of preparing each state at the end of the ramp sequence against the ramp time is plotted in FIG. 5E with dashed lines.

When Δv₁=Δv₂=0, the only interacting states are the singlet states. In this case, the figure shows the reducing probability of initialising |S(0,2) [symbol] as the ramp time increases, and the increasing probability of initialising |S(1,1) [symbol] . A ramp time of 1 μs is sufficient to initialise |S(1,1) [symbol] for the parameters shown in FIG. 5.

Moving onto the initialization of |T_{-,p} [symbol] , we look at the case where Δv₁=−Δv₂. An anti-crossing between |S(1,1) [symbol] and |T_{-,p} [symbol] is now present, as shown in FIG. 5B. As before, ∈ is ramped from a positive energy to a negative energy for different ramp times. The probability of preparing each state against the ramp time in plotted in FIG. 5E with solid lines.

The introduced condition Δv₁=−Δv₂ allows for the |T_{-,p} [symbol] state to be initialized at a ramp time of approximately 110 μs. Before |T_{-,p} [symbol] is fully initialized, both |S(1,1) [symbol] and |T_{0,p} [symbol] interact due to the coupling term. Similar to the case with no coupling term, as the ramp time approaches 1 μs, the |S(1,1) [symbol] state becomes more probable. Increasing the ramp time further, the state is able to adiabatically cross the lowest energy anti-crossing and initialize |T_{-,p} [symbol] .

From the two examples discussed above in FIGS. 5A and 5B, it is clear that the lowest energy anti-crossing has an impact on how the states are initialized.

The transformation from the rotating bare spin basis to the dressed spin basis is unitary. This means that the eigenenergies of the system remain the same for this change of basis. Thus, the lowest energy splitting should be the same value in both the rotating bare spin and dressed spin cases. This means that the anti-crossing is proportional to Δv₁−Δv₂.

The importance in understanding the lowest energy anti-crossing becomes more apparent when the variability between the different qubit environments is regarded. It is common for there to be a difference in g-factors between a pair of spins in quantum dots, therefore the values of Δv₁ and Δv₂ will typically be different. Although the external global field 302 can be rotated to an angle that minimizes the difference between the two g-factors, for larger scale systems there will still be variability. This means that the scenario including the lowest energy anti-crossing (in FIG. 5B) may be more realistic.

Readout of a dressed qubit follows a similar method to initialization. Instead of ramping e from positive to negative energies, the reverse is implemented. The ramping is chosen at a particular rate so that it allows for |S(1,1) [symbol] to tunnel into |S(0,2) [symbol] , but not the triplet states. This is the same singlet-triplet readout technique used for rotating bare spin qubits. Dressed parity readout is also achievable when considering dephasing in the system since the Pauli spin blockade is still active, so it follows similar dynamics to the rotating bare spin case.

### Single Qubit Control

For universal quantum computation a qubit system must have control about two axes. For the dressed qubit, single qubit gates can be achieved by pulsing the amplitude of the detuning Δv. The detuning Δv is the relative shift between the qubit and microwave frequency, Δv=f₀−f_{mw}.

Single-qubit control of the dressed qubit can be implemented in one of two ways. The first control method is dependent on the range of control one has of the Stark shift of a given qubit. The exact range can be calibrated by a spin spectroscopy method where the frequency of the applied microwave pulse is varied together with the relevant gate voltages. Resonance is obtained at different frequencies depending on the voltage, determining the maximum range of Stark shifts and the amplitude of the voltage pulse needed to achieve such range. If this range is larger than the magnitude of the Rabi frequency Ω_{R}, then the qubit Larmor frequency f_{Q} can be shifted electrically such that the spin is no longer in resonance with the global field frequency f_{mw}.

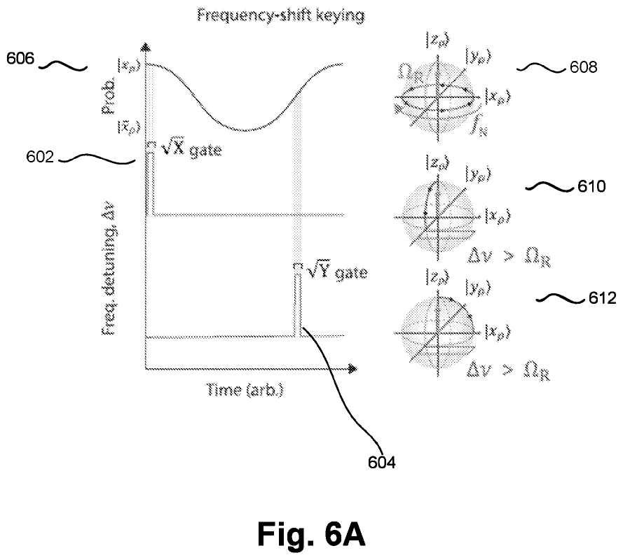

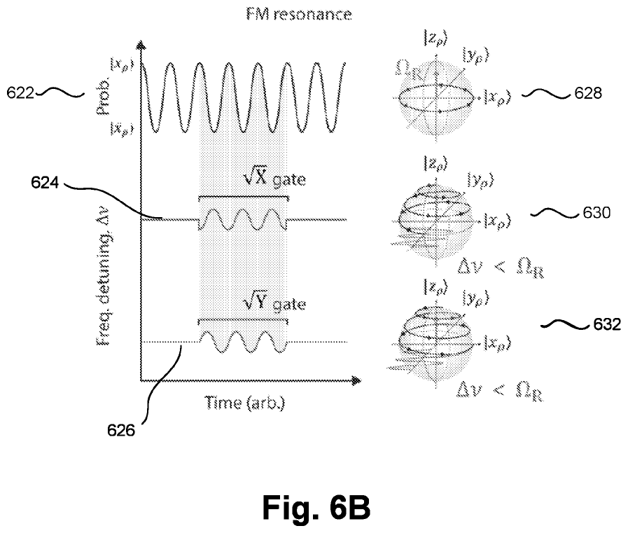

The detuning Δv=f_{Q}−f_{mw} has the effect of halting the nutation of a given qubit leading to X rotations relative to the frame in which the qubits 304 in the dressed protocol are defined. This method is called frequency-shift keying and is shown in FIG. 6A. Frequency-shift keying is a frequency modulation scheme where changes to the frequency are discreet. That is, the detuning Δv is modulated by a square pulse (such as square pulses 602 and 604 shown in FIG. 6A).

In this case, two-axis control is obtained by defining a nutating frame—i.e., a frame in which the x-y plane in the rotating frame is also rotating. This can be at a frequency f_{N} that is slightly slower or faster than the Rabi frequency defined in the rotating frame, such that the timing at which the detuning pulse that is applied sets whether the qubit is rotated about the x or y-axis in the dressed nutating frame. This is analogous to IQ modulation methods used to perform x and y rotations of traditional bare spin qubits.

The left panel of FIG. 6A shows the probability of a given qubit being in dressed state |xₚ [symbol] or |x̅ₚ [symbol] (see plot 606) and the right panel shows a Bloch sphere representation of the dressed qubit (see Bloch sphere 608). The Bloch sphere representation of the dressed qubit 608 is on resonance with the global field 302 and as such it precesses between the states |xₚ [symbol] and |xₚ [symbol] shown by the directional circle in the x-y plane of the Bloch sphere 608.

The transformation to the nutating frame adds a time dependence to the detuning Δv such that square pulses can be timed to be out of phase with respect to each other, leading to an X gate or Y gate. The X gate pulse 602 and Y gate pulse 604 are shown relative to the probability of the qubit being in state |xₚ [symbol] or |x̅ₚ [symbol] . The corresponding Bloch sphere representations showing the dressed spin performing π/2 gates are shown in 610 and 612, respectively.

The second strategy for creating two-axis rotation is based on a second level of resonance, shown in FIG. 6B. In this case, the detuning between the qubit Larmor frequency and the microwave frequency of the global field 302 is modulated by shifting the Larmor frequency sinusoidally at a frequency that matches the amplitude of the Rabi frequency Ω_{R} (this is referred to as FM resonance method in this disclosure). This modulated detuning pulse can lead to x or y rotations depending on whether it is a sine or a cosine frequency modulation.

FIG. 6B also includes a left panel and a right panel. The left panel shows plots of the probability of the qubit being in dressed state |xₚ [symbol] or |x̅ₚ [symbol] 622, and X and Y gate pulses 624, 626 on the detuning, respectively. The right panel shows corresponding Bloch sphere representation of the dressed qubit. As seen in Bloch sphere (628) is on resonance with the global field and as such it rotates between the dressed states |Xₚ [symbol] and |xₚ [symbol] .

Applying a sine modulation to the detuning (as seen in plot 624) yields a rotation about the x-axis as shown in the Bloch sphere representation 630. A phase can be added to the modulation so that the amplitude of the detuning follows a cosine wave (as seen in plot 626), thus performing a rotation about the y-axis. This rotation about the y-axis is shown in the Bloch sphere representation 632 of the dressed qubit.

Frequency-shift keying can lead to faster two qubit gates, but may require more range of control of the detuning. Particularly, the range of Stark shift control needs to exceed the Rabi frequency, which in turn needs to be larger than the natural variability of the qubit frequencies between the multiple dots. The actual range of detuning will depend on the architecture of the quantum processing system on which this is applied. The FM resonance method on the other hand works for small frequency shifts. However, the smaller the range of gate-induced detuning shift, the slower the gate becomes using this method.

### Two-Gubit Control

It is important to understand the origin of two-qubit gates for universal quantum computing in the dressed picture. The intrinsic gates discussed here are the SWAP gate and CPHASE gate. It will be appreciated that these gates are selected merely as examples and the techniques described herein can be used to control other gate operations without departing from the scope of the present disclosure.

A two-qubit gate is a controlled operation between two qubits in the quantum computing system. Referring to FIG. 3A a two qubit gate may be performed between two qubits 304 in the qubit array. For example, qubit 304A and qubit 304C may be targeted to perform a two-qubit gate. In other embodiments, any pair of qubits 304 in qubit array may be targeted to perform a two qubit gate.

Two-qubit gates can be performed by pulsing the voltage on a gate electrode 306 between corresponding quantum dots or by detuning one quantum dot with respect to another, creating a controllable exchange coupling. The resulting gate-whether it is a SWAP or CPHASE gate—is dependent on system parameters.

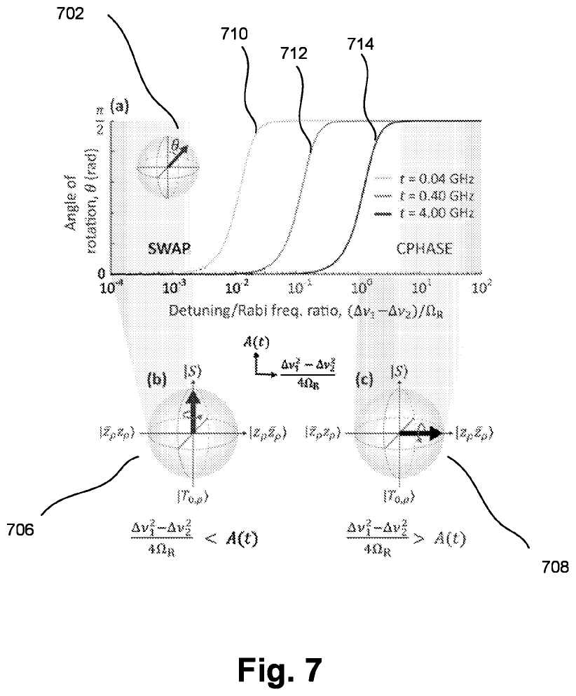

For qubits with the same Larmor frequency and the same Rabi frequency throughout the pulsed gate sequence, the exchange coupling results in a SWAP gate. This is demonstrated in FIG. 7. In particular, FIG. 7 depicts two-qubit gate operations. The top plot 702 shows the transition of the SWAP gate regime into the CPHASE gate regime. The horizontal axis of plot 702 shows frequency detuning difference (Δv₁−Δv₂) over the Rabi frequency of both qubits. Three curves (710, 712, 714) are shown in plot 702, each for a different tunnel coupling rate. In particular, curves 710, 712, and 714 represent the transition for tunnel coupling rate 0.04 GHZ, 0.40 GHZ, and 4.00 GHZ, respectively.

As seen in plot 702, the transitions of the SWAP regime into the CPHASE regime can be controlled by the relative frequency detuning between the two qubits. This detuning can be controlled by applying voltages to gate electrodes 306. For example, in FIG. 3A the voltages applied to gate electrodes 306A and 306C can affect the qubit frequency of qubits 304A and 304C respectively. Further, FIG. 7 shows the corresponding Bloch sphere representation of the SWAP gate 706 and the CPHASE gate 708 for the two-qubit gate.

The tunnel rate between spin qubits in quantum dots is typically of the order 1 GHZ. The phase transition between the SWAP gate and CPHASE gate depends on the tunnel coupling.

Although the goal is to have a qubit array system where all Larmor frequencies can be tuned to the same value, a more realistic case is one in which gate pulsing causes some level of detuning of the Larmor frequencies. Moreover, potentially the Rabi frequencies of the two qubits in a gate operation are not identical. In either case, the resulting two-qubit operation is dependent on the comparison between the relative detuning between the Rabi frequencies and the rate at which the tunnel coupling is turned on and off. For slowly activated tunnel coupling, the detuning (or Rabi frequency difference) causes an averaging of the scalar product between the transversal components of the spins that rotate in the dressed protocol, resulting in interactions only along the quantization axis (ZZ interactions).

If the exchange coupling is activated with a fast pulse, the product of the transversal spin components does not average to zero and a SWAP gate is recovered. The gate implemented by a ramp that is neither too fast nor too slow is dependent on the ramp rate itself and can only be studied case by case.

In a similar way, qubit readout and initialization are impacted by differences in qubit detuning or differences of Rabi frequencies, and the result of a ramp from the (1,1) electron configuration in a double quantum dot to a (0,2) configuration will depend on how the ramp rate of the energy detuning between the two quantum dots (Δv₁−Δv₂) compares to the frequency detuning between spins.

Effects of noise and variability between quantum dot properties and how it impacts the global control technique is described next.

As described previously in relation to single qubit gates, the desired gate strategy is influenced by the range of the Stark shift that can be induced in a given qubit by gate voltages. This, on the other hand, is set by the type of spin-orbit coupling that predominantly affects the qubit. In an approximately atomically flat interface between silicon and a barrier (such as silicon dioxide), the type of spin-orbit coupling can be controlled by applying the external DC magnetic field in different directions. A magnetic field pointing along either the (100) or (010) directions for a quantum dot formed against a (001) interface removes the impact of Dresselhaus spin-orbit effects on the qubit Larmor frequency, resulting in a Rashba-only spin-orbit coupling, i.e., a two-dimensional spin-orbit interaction. On the other hand, for a DC magnetic field along (110) or (1-10) the Dresselhaus effect is present, usually dominating over the Rashba spin-orbit coupling.

A Dresselhaus effect is the result of the atomically flat interface between silicon and a barrier, resulting in removal of inversion symmetry present in the bulk of silicon. Because this effect is intrinsically determined by the interface, it is strongly affected by the electric field that presses the electron wavefunction against the interface, as well as by the interface roughness and variability from dot to dot. This means that, for a DC magnetic field pointing along the (110), a maximum Stark shift is obtained nearing ±70 MHZ/T. (typically controlled by the top gate or next nearest gate). On the other hand, the g-factor of the electrons at the same vertical electric field have the most variation, with a range that can be as large as 80 MHz/T. While the Stark shift can be used to potentially tune electrons closer to some point of minimal variation between Larmor frequencies, having all qubits on resonance with the external AC global field 302 within a range that does not exceed the Rabi frequency Ω_{R}, might require using small magnetic fields (unless very high Ω_{R}, of the order of 10-100 MHZ is achievable).

On the other hand, a DC magnetic field pointing along the (100) direction can lead to a maximum variability of Larmor frequencies of 20 MHZ/T, but more typical values are below 5 MHz/T. This relaxes the condition on both the DC external magnetic field (which can be as high as hundreds of mT) and on the Rabi frequencies (which can be lower than 10 MHz). On the other hand, this field direction limits the Stark shift to no more than 5 MHz/T.

The realistic variability between quantum dot properties highlights the importance of added robustness against frequency detuning noise and inhomogeneity.

### Example Quantum Processing System Based on the SMART Protocol

The strategy for universal quantum computation described above can be used in a more general context. Qubit initialization, two-qubit gates and readout described above were based on how spin singlets are independent of the choice of basis/frame. This means that a more advanced always-on global driving field may not have a negative impact on these operations, but can potentially improve the system's robustness to noise, variability, and imprecisions in control pulses.

Noise is generally time dependent. Even though to a large extent the most damaging noise occurs at time scales that are long compared to most experiments, the noise at frequencies above 100 kHz has an impact on spin qubits, limiting the coherence time as observed in refocusing experiments such as Hahn echo or CPMG.

In some cases, the amplitude of the global microwave signal 302 can be engineered to be modulated in a way that cancels out these higher order noises. For instance, inventors of the present disclosure found that a more general parametrized driving amplitude modulated by a sinusoidal shape leads to a free parameter—the modulation frequency f_{mod}, which can be selected to cancel out second order noise.
Global modulation: A cos (2πf_{mod}t+ϕ_{global})

The modulation phase ϕ_{global} is another free parameter that affects the required Stark shift control to perform traditional x- and y-axis rotations. Specifically, ϕ_{global}=π/2 and ϕ_{global}=0 are studied. The amplitude relative to the modulation frequency is also of importance and can be used to cancel out noise.

As described previously, aspects of the present disclosure introduce a method of dressing a qubit with an oscillatory driving field that has a time-dependent amplitude, such that the amplitude modulations create an effectively time-dependent Rabi frequency. By engineering the amplitude modulation frequency to be in a certain proportion with the Rabi frequency, different types of noise can be cancelled. In general, multiple types of noise can be targeted by adding different frequency and phase components to the amplitude modulation.

The choice of frame used to describe a qubit subject to a sinusoidal global driving field helps understand this technique for qubit control. Following the frame used for the dressed protocol above, a Hadamard transformation can be applied to the rotating frame. In this frame, an “idle” qubit in the SMART protocol is driven by the sinusoidal driving field 302, and is not actually idle/still, but oscillating back and forth about the driving field axis. In order to describe the SMART technique in the traditional way, where any initialized state is static (not oscillating), an oscillating frame has to be implemented. The analogous situation for bare qubits is when one considers a rotating frame that removes the spin precession that results from a static B-field.

Note that the frequency of modulation f_{mod} sets a minimum bandwidth for the source of the electromagnetic microwave radiation. This can be a limiting factor for the use of high-quality factor resonators. Nevertheless, most resonators that would be used for this purpose have bandwidth in excess of tens of MHz, which is sufficient for the purposes discussed here. Moreover, the coupling between the resonator and the microwave source can always be increased in order to reduce the quality factor and achieve the necessary bandwidth.

The frequency f_{mod} that optimises the noise cancelling properties of the microwave drive field 302 is that which leads to a simultaneous echoing of the first and second order terms of a Magnus expansion. This can be either found by a theoretical analysis of the Magnus expansion or by experimentally calibrating the value of f_{mod} that maximally protects the qubit in any superposition state. The theoretical analysis of the Magnus expansion returns the Bessel function of zeroth order when setting ϕ_{global}=0.

Note that the sinusoidal modulation of amplitude affects all qubits 304 in the qubit array simultaneously. The qubit states in this technique are more intricate, being defined as observed by a reference frame that rotates back and forth, nutating in one or another direction depending on the microwave amplitude.

Single qubit operations in this technique also rely on individual Stark shifts, which can be implemented by frequency modulation with a frequency matching the amplitude modulation (or some harmonic) of the global field 302. Depending on the quadrature of the frequency modulation, the implemented single qubit gate may be directed along x, y or any other direction in the x-y plane. This is referred to as a quadrature amplitude modulation (QAM) method. These gate operations rely on the Larmor frequency of the qubits being changed synchronously with the amplitude modulation of the global field via their Stark shifts. It should be noted, however, that this description of controlling the frequency detuning with Stark shifting the Larmor frequency in spin qubits can be extended to other qubit systems where alternative methods of controlling the frequency detuning would be equally valid.

For a sinusoidally modulated global drive field where (ϕ_{global}=π/2) a simple sinusoidal modulation of the Stark shift amplitude does not implement orthogonal rotation axes. The ideal implementation of x and y rotations is given by combining a few harmonics in an analytical way.

$$Stark shift : {α}_{x / y} sin ( 2 π {f}_{mod} + {ϕ}_{mod} ) + {β}_{x / y} sin ( 4 π {f}_{mod} t + {ϕ}_{mod} )$$

Where ϕ_{mod} is phase of the Stark shift AC control. For a global drive field with sinusoidal modulation and (ϕ_{global}=0), on the other hand, the first and the second harmonics alone can be used for Stark shift amplitude modulation to create x- and y-rotations, respectively.

Another interesting feature of this control technique is related to elementary two-qubit gates. Due to the increased resilience to deviations from resonance, this strategy for global control more efficiently implements SWAP gates, even in the presence of larger detuning between qubits.

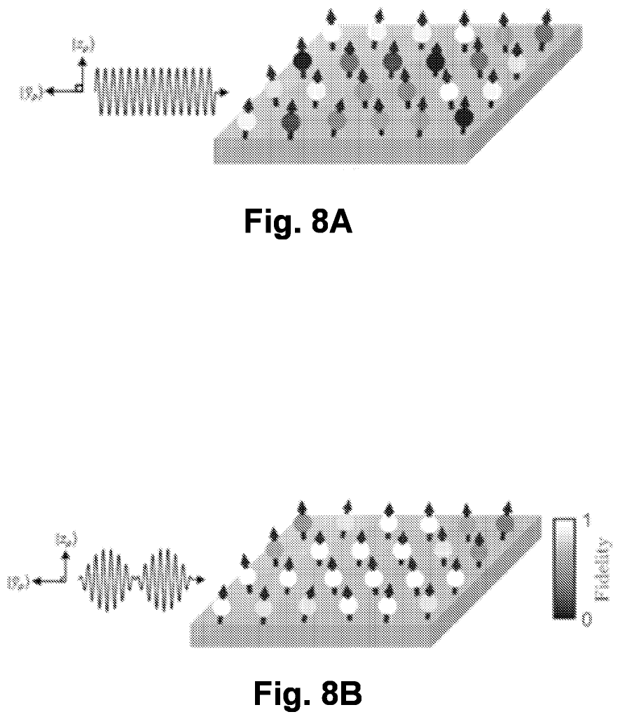

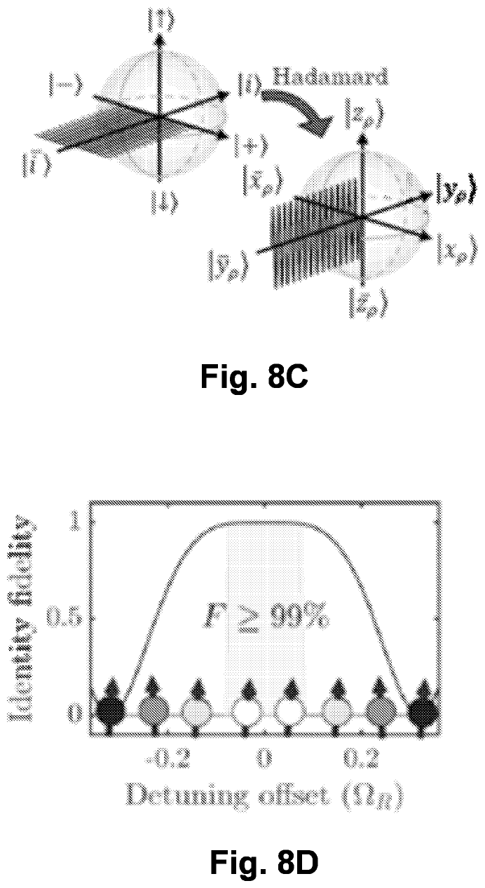

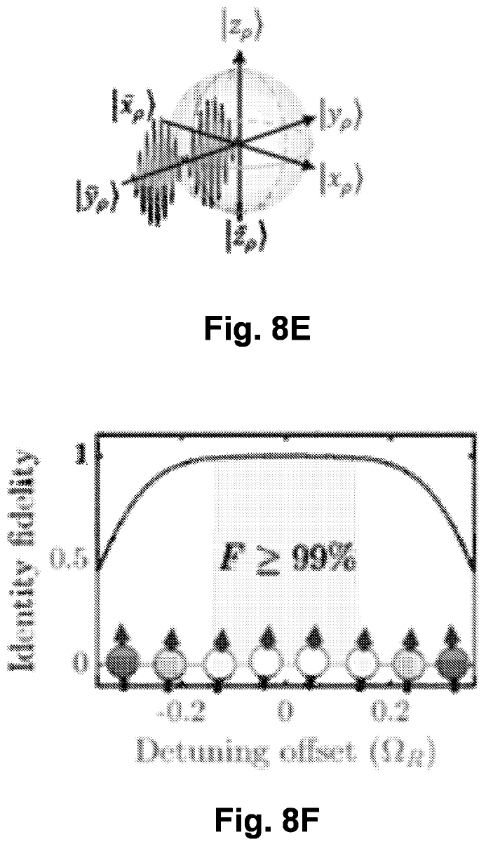

FIG. 8A shows a qubit array driven collectively by a global field consisting of a continuous drive. FIG. 8B shows a qubit array driven collectively by a global field consisting of a sinusoidal modulated field. The Bloch spheres for the continuous drive are shown in FIG. 8C together with the transformation from the bare to the dressed spin frame. FIG. 8D shows the identity operator fidelity for a range of detuning offsets where the range with fidelities above 99% has been shaded. The Bloch sphere and the identity operator fidelities for the sinusoidal modulated case are shown in FIGS. 8E and 8F. In this simulation, the Rabi Frequency is 1 MHZ. As seen in this figure, the range of detuning offsets with fidelities above 99% is greater when using the SMART technique when compared to the dressed technique.

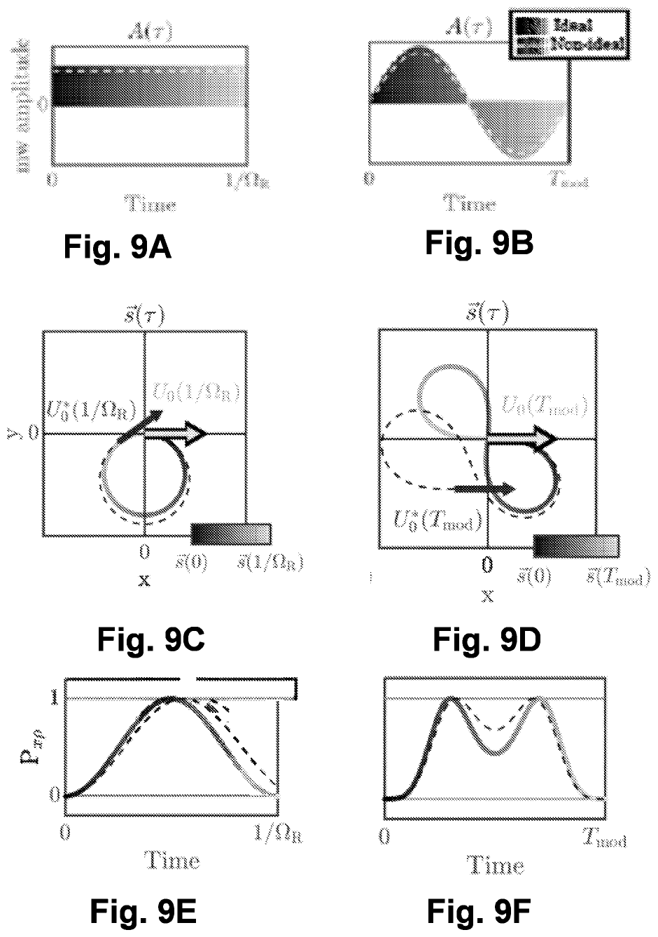

FIG. 9, shows geometric formalism describing noise-cancelling properties. In particular, FIGS. 9A and 9B are plots showing global field amplitude modulation A(τ) as a function of time for dressed and SMART techniques. FIGS. 9C and 9D show the corresponding space curves \vec{s}(τ) calculated from Magnus expansion series, for the dressed and SMART technique. The curvature of \vec{s}(τ) k corresponds to A(τ). In these figures, the ideal modulation condition (perfect noise cancellation) is plotted with a solid line and a non-ideal condition with a dashed black line. The evolution of a qubit initialized to xₚ [symbol] is shown in FIGS. 9E and 9F for the dressed and SMART techniques, respectively. FIGS. 9A-9D, show a closed space curve (solid line), a circle for the dressed case and a figure eight for the SMART case. The dashed line in FIGS. 9C and 9D shows the case where the amplitude is offset for the same gate time, resulting in a non-closed space curve or equivalently non-ideal noise cancellation.

The geometric requirement for first order noise to cancel is that s (t) is a closed curve (\vec{s}(0)=\vec{s}(τ)). In order for second order noise to cancel as well, the projected area from \vec{s}(τ) onto the x-y, x-z and y-z plane must all equal zero. The sign of a projected area is determined by the winding direction of the space curve, hence the figure eight lobe in the fourth quadrant (in FIG. 9D) has positive sign, and the one in the second quadrant has negative sign. The projected areas therefore sum to zero for the sinusoidal driving field, but not for the continuous drive which has a net circular area projected onto the x-y plane. Hence, where the SMART technique cancels out both first and second order noise, the dressed qubit only provides first order noise cancellation.

Information about the single-qubit operator can be found in the slope of \vec{s}(τ) at τ=0 relative to τ=T. Parallel slopes correspond to the identity operator, which is the case for the ideal noise cancellation in FIG. 9D represented by U₀(T) (black and beige arrow parallel). Perpendicular slopes correspond to \sqrt{X} and \sqrt{Y} gates etc. The optimal modulation conditions for the global field can be identified by forcing the first and second order Magnus expansion series terms to zero. The optimal modulation frequency f_{mod}^{opt} is found to have the following relation with Ω_{R}

f_{mod}^{opt}=Ω_{R}\sqrt{2}/πfᵢ (4)

where j, is solution i to the Bessel function of zeroth order.

The duration of one period of the global field is denoted T_{mod}. For a SMART qubit initialized in the plane perpendicular to the global field axis, driven at f_{mod} with normalized amplitude and Δv (T)=0, a positive rotation of ˜3π/2 followed by a negative rotation of the same angle occurs for every T_{mod} of the global drive, as shown in FIG. 9B. The dressed qubit on the other hand continuously rotates without change in angular acceleration. The back and forth rocking of the SMART qubit and the continuous rotation of the dressed qubit about the global field axis contributes to continuous echoing.

Note that the resulting control axes that emerge from this modulation scheme are not parallel to the coordinate system used to describe the Hamiltonian. Instead, the rotation axes w and v can be calculated from the time evolution operators.

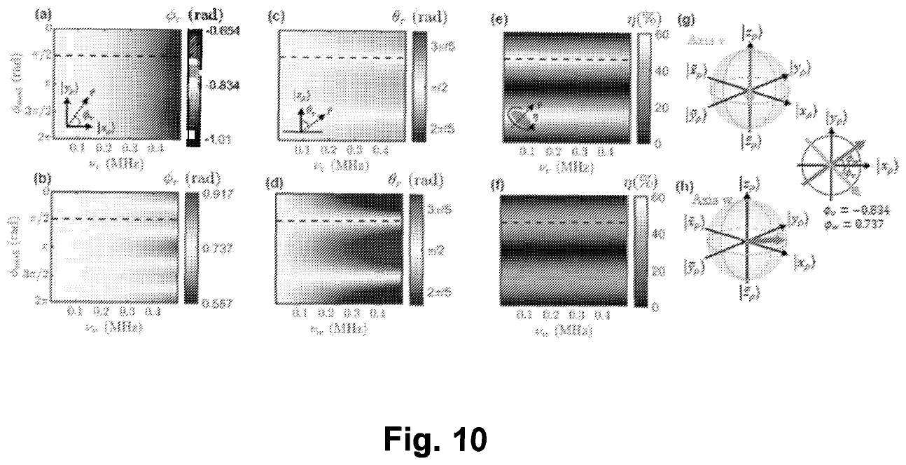

FIG. 10A shows rotation axis parameter ϕᵣ for axis vᵥ. FIG. 10B rotation axis parameter ϕᵣ for axis v_{w}. FIG. 10C shows rotation axis parameter θ, for axis vᵥ and FIG. 10D shows rotation axis parameter or for axis v_{w} of the SMART method for different values of control amplitude V_{v,w} and phase offset between the global microwave field 302 and the gate modulation ℠_{mod}. The rotation axes are diagonal to the axes of the coordinate system. Phase π/2 has been indicated with a dashed horizontal line. The rotation efficiency η is shown in FIGS. 10E and 10F with the maximum values of 53.9% and 37.3% for axis v and w, respectively. The rotation efficiency η which is given as a function of ϕ_{mod} and V_{v,w}. This value is calculated according to:

$${η}_{v , w} = 100 \% \times \frac{{x}_{v , w}^{2}}{2 {π}^{2} {T}_{mod}^{2} \sum {v}_{v , w}^{2}}$$

and is 100% for square pulse control of a bare spin and 50% for the dressed spin. This shows that both v and w rotations have comparable control strength to the dressed spin qubit.

For small values of v_{v,w} and ℠_{mod}=π/2 the resulting pair of perpendicular axes of rotation are illustrated on Bloch spheres in FIGS. 10G and 10H with a relative angle of ϕᵥ=0.834 radians to the dressed x-y axis system. Here 12R=1 MHz. In order to assess the SMART qubit method gate robustness to frequency detuning and microwave amplitude fluctuations a noise analysis is carried out.

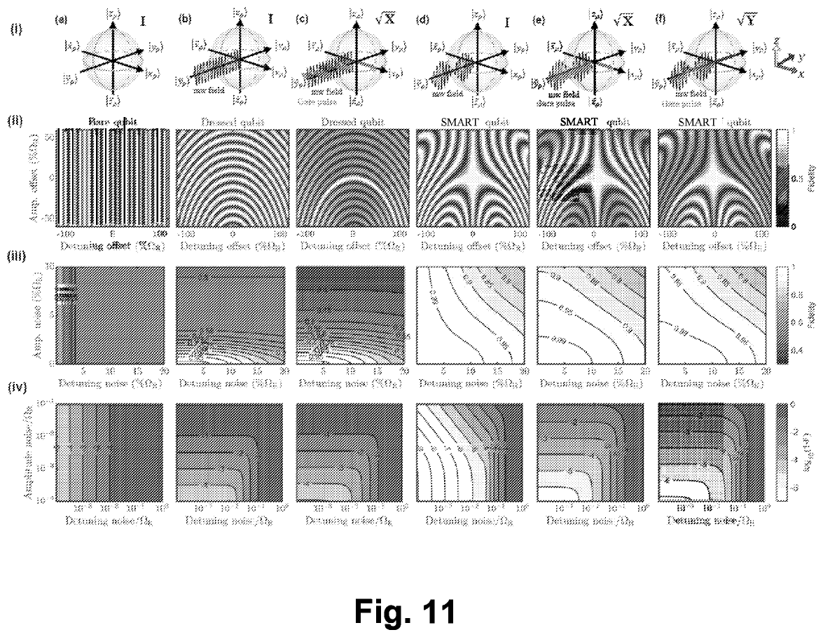

FIG. 11. Shows gate fidelities for different values of amplitude and detuning offset/noise for the bare, dressed and SMART spin qubit. In particular, FIGS. 11A-11C show the identity gate fidelities for the bare, dressed spin qubit, and an \sqrt{X} gate operation for the dressed qubit, respectively. In FIGS. 11D-F, SMART qubit method identity, \sqrt{X} gate operation and \sqrt{Y} gate operation is shown. The first row of figures shows Bloch spheres with the relevant global field, local control field and rotation axis. In the second row, the fidelity for offset values of amplitude and detuning is shown. Finally, the third and fourth rows show Gaussian distributed noise in linear and log scale, respectively. In these examples, Rabi oscillation is considered to be 1 MHz.

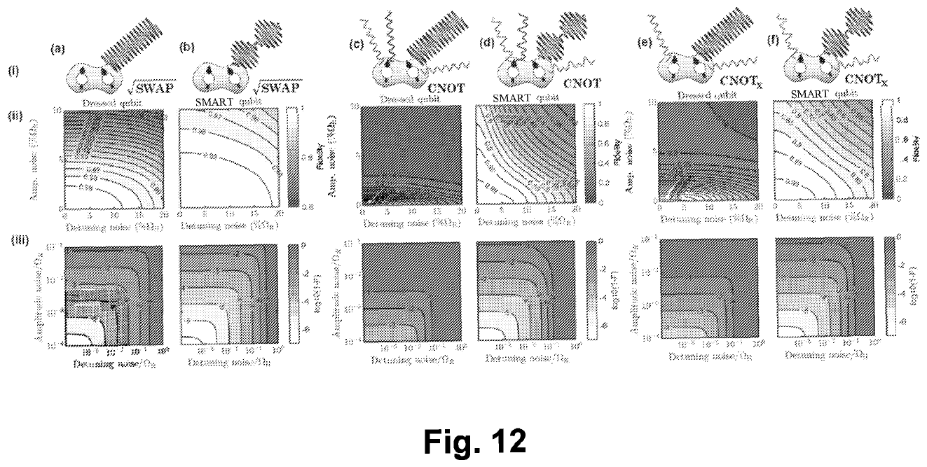

FIG. 12A shows two-qubit \sqrt{SWAP} gate fidelities for the dressed qubit and FIG. 12B shows two-qubit \sqrt{SWAP} gate fidelities for the SMART qubit. In FIGS. 12C and 12D, the gate fidelities for two-qubit CNOT gate for the dressed qubit and SMART qubit methods is given. FIGS. 12E and 12F show two-qubit CNOTx gate fidelities for the dressed qubit and SMART qubits respectively. The first row shows two qubits with a common global field and local Stark shift fields. In the second and third rows the gate fidelities with Gaussian noise applied are shown on a linear and log scale, respectively. Here 12R is 1 MHZ.

The \sqrt{SWAP} gate is implemented assuming exchange gate control, where SWAP-like operation is the native two-qubit gate for qubits having the same resonance frequency. The CNOT and CNOTx gate sequences used here are (\sqrt{Y}^{†}⊗1)\sqrt{SWAP}(\sqrt{X}^{†}⊗\sqrt{X})\sqrt{SWAP}(\sqrt{Y}⊗1) and \sqrt{SWAP}(\sqrt{x}^{†}⊗\sqrt{X})\sqrt{SWAP}, respectively.

Here the assumption that the two qubits experience the same noise level is made. For both one- and two-qubit gates the robustness to detuning and amplitude noise is seen to improve in the SMART case compared to the bare and dressed case. From the log scale results, this improvement corresponds to close to an order of magnitude, corresponding to one order of magnitude more fault-tolerant gates in the same noise conditions.

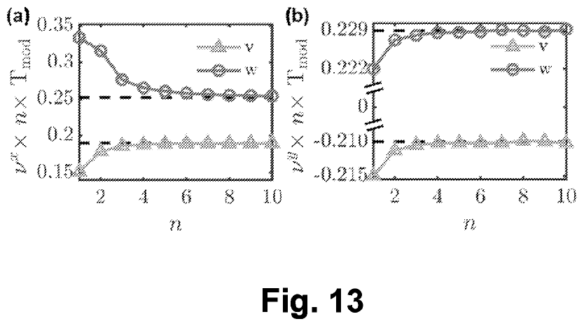

FIG. 13 shows coefficients vᵥ and v_{w} times the duration of a gate for \sqrt{X} (FIG. 13A) and \sqrt{Y} (FIG. 13B) gates for different gate durations. The dashed horizontal line indicates the convergence value. Note that in FIG. 13B the y-axis is discontinuous. As seen in these figures, the coherence values clearly converge at longer gate duration. This convergence comes from the Rotating Wave Approximation (RWA) where for large driving amplitudes the approximation breaks down. There is a compromise between accurate rotation axis and fast control, as choosing a small integer number n for the gate duration forces vᵥ and v_{w} higher to achieve the same rotation angle, affecting the accuracy of the rotation axis θᵣ and ϕᵣ. The fastest possible gate is limited by the Stark shift in the system and Ω_{R}(T_{mod} ≡1/Ω_{R}).

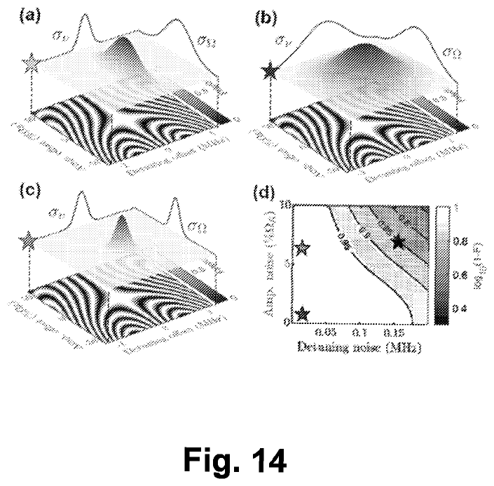

FIG. 14 shows a schematic of the method used to construct a Gaussian noise model. The fixed offset noise map is multiplied by 2D Gaussians with σₓ and σ_{y} corresponding to the detuning and amplitude noise levels, shown here for three different cases in FIGS. 14A-C. The colored stars in FIG. 14D indicate the following: low detuning noise and high amplitude noise (yellow), high detuning noise and high amplitude noise (red) and low amplitude noise and low detuning noise (green).

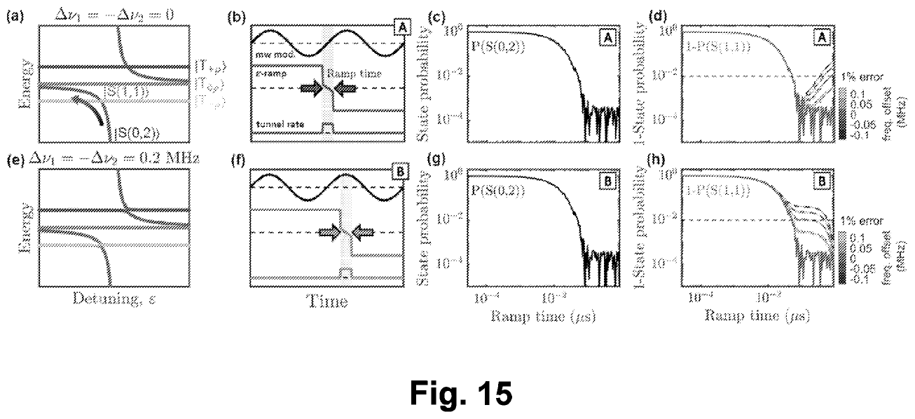

FIG. 15 shows a schematic of two-qubit initialization and readout using the SMART technique. In particular, FIG. 15A shows an energy diagram of the SMART two-qubit system for zero frequency detuning and with Δv₁=−Δv₂=0. For non-zero frequency detuning an anticrossing appears and the ramping rate determines whether or not the spin crosses this energy anticrossing diabatically. The system is initialized to a S(1,1) state from a S(0,2) state with a ramp centered about either the minimum or the maximum microwave amplitude (A and B), as illustrated in FIG. 15B. The transition from positive to negative detuning consists of a step before and after the slow ramp to achieve lower ramp rate, as seen from ε-ramp in FIG. 15B. The results with different ramp rates and fixed charge detuning ramp range 50 GHZ→−50 GHz (˜0.2 meV) is shown in FIGS. 15C and 15D where the probability of S(0,2) and S(1,1) is plotted against ramp time. Fixed offsets in frequency detuning (Δv₁, Δv₂) are introduced, with magnitudes given by the colorbar (two-colored dashed line representing the two qubits). In FIG. 15E an energy diagram with Δv₁=−Δv₂=0.2 MHz is given. Initialization with the ramp centered about the maximum microwave amplitude and the corresponding singlet S(0,2) state and S(1,1) state probabilities are given in FIGS. 15 F-H. Parameters used here include (Ω_{R1}=Ω_{R2}=1 MHz, (Δv₁, Δv₂)∈{0,±0.05, ±0.1}MHz, t=0.5 GHz. The total time is 2×T_{mod}.

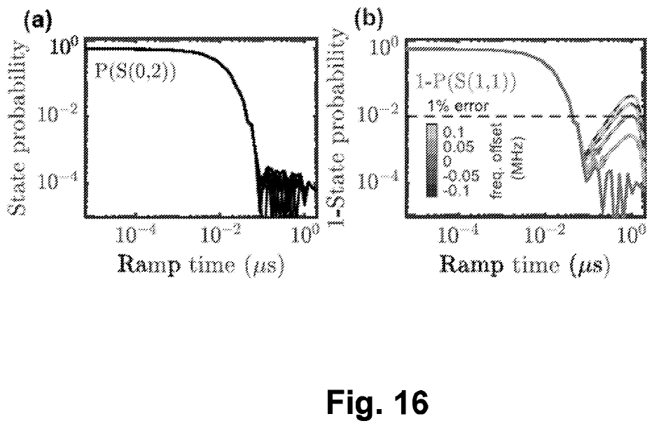

For comparison, two-qubit dressed initialization is shown in FIG. 16. In particular, FIG. 16 shows dressed two-qubit initialization for different ramp times and frequency detuning offsets. The state probability of S(0,2) and S(1,1) is shown with Ω_{R}=1 MHz and the total time 2/Ω_{R}. To show the robustness to resonance frequency variability different combinations of Δv₁ and Δv₂ ∈{0, ±0.05, ±0.1}MHz are simulated. A S(1,1) state is achieved with >99% fidelity after approximately 0.1 μs for case A and 1 μs for case B (at worst-case frequency offset). Centering the ramp about the minimum microwave amplitude (A) looks to be a more robust option causing less mixing with the triplet states. This can be understood by comparing how much echoing is achieved in either case. For case A close to a full period of the global field follows the ramp, whereas for case B less than three quarters of a period. Readout can be performed similarly by reversing the process described above and relying on Pauli Spin blockade in the dressed frame.

### Prototyping Results

Electron spin resonance (ESR) experiments were conducted on a single qubit system in order to prototype some of the principles behind the SMART technique.

This experiment does not cover all aspects of universal quantum computation, and is focused on comparing single qubit performance of a spin using the bare, dressed, and SMART techniques for global control.

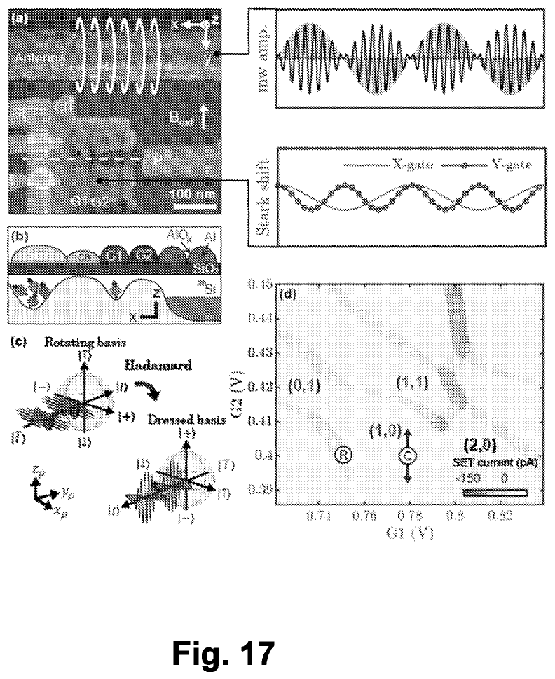

The experimental apparatus is shown in FIG. 17. As seen in FIG. 17A, the apparatus 1700 includes an arrangement of electrodes (G1, G2) that have voltage biases applied to them in order to isolate a single electron 802 in a quantum dot under the gate electrode G1. The gate electrode G2 controls the barrier between said quantum dot and a reservoir (R) of electrons under the other gate electrodes. Further, gate G2 is pulsed to control the qubit through Stark shift. The number of electrons under G1 is counted based on variations of current characteristics sensed in the single electron transistor (SET) fabricated nearby. A global microwave field is applied to this experimental apparatus 1700 to simulate the bare, dressed and SMART control techniques. FIG. 17A also shows an amplitude modulated sinusoidal global field 1704 applied to the apparatus 1700 and a plot 1706 showing the x gate and y gate modulated signals applied to the qubit via the electrodes G1, G2.

FIG. 17B shows a cross-section of the device from the dashed line shown in FIG. 17A. As seen in FIG. 17B, the quantum dot is formed at the interface between a silicon 28 substrate and a silicon dioxide layer. FIGS. 17C and 17D show the basis transformation and the qubit stability diagram used for readout, respectively.

### Experiment 1: Coherence Time of Qubits in the Dressed and SMART Protocols

In a first experiment, a given qubit (e.g., qubit 304A of the qubit array of FIG. 3A) is prepared in the |i) state, and is subject to a continuous driving microwave field 302 (i.e., constant for the dressed control method and sinusoidally modulated for the SMART control method) for a certain wait time. Subsequently, the qubit is projected back onto the measurement basis and the state probability is recorded (similar to traditional Ramsey experiment). The decay rate of the qubit indicates the noise performance of the continuous driving.

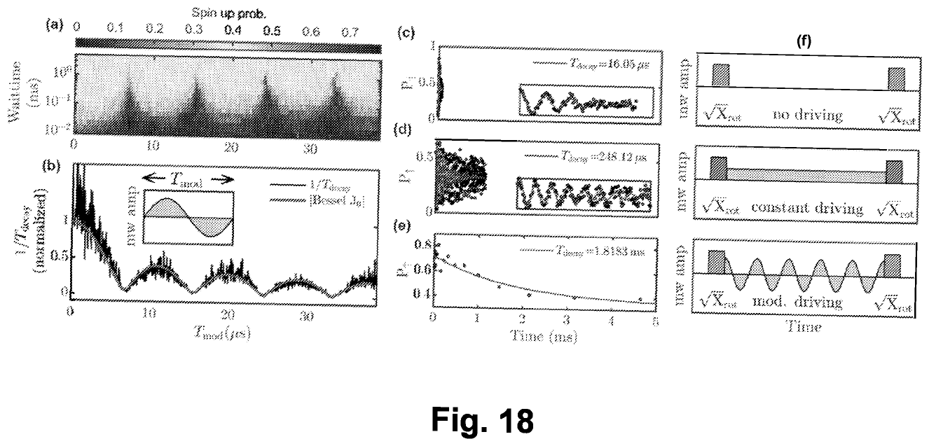

FIG. 18 shows the Ramsey experiment using the SMART qubit method. In particular. FIG. 18A shows the Ramsey experiment results where the period of the global modulated field is varied. FIG. 18B shows extracted decay rates (black line) fitted to the absolute value of the Bessel function of zeroth order (red line). FIGS. 18C and 18D show comparison between bare qubit (100 shots, six repeats), dressed (300 shots, two repeats) and SMART qubit method (at T_{mod}=24.12 μs) decay times (left column), together with the respective microwave pulse sequences (right column). In this experiment, \sqrt{X}ᵣₒₜ is in the rotating basis.

Driven spin qubits are dominated by noise at the frequency of the driving field 302. For the SMART qubit method with a modulated driving field, the coherence time is also sensitive to the initial state in the plane perpendicular to the quantization axis. T_{decay} is defined as the measured coherence time of the spin rotation resulting from the driving field, when initialized to |i [symbol] .

After initializing the qubit to |i [symbol] via a π/2 rotation about i (x in the rotating frame) the modulated driving about the same axis is turned on for a certain wait time, t_{wait}, followed by a final π/2 rotation about i[\sqrt{X}ᵣₒₜ−t_{wait}−\sqrt{X}ᵣₒₜ see FIG. 18E. The spin is then measured every n-th period of the sinusoidal modulation, where the modulated driving itself ideally equates to an identity operation after every period. By keeping Ω_{R} fixed and varying the period T_{mod}, the 2D map in FIG. 18A is acquired. Similarly, T_{mod} can be kept fixed while varying Ω_{R}. The data is fitted according to an exponential decay ≡e^{-t/T}^{_{decay}}, resulting in the decay rate plotted in FIG. 18B. The decay rate closely resembles the absolute value of the zeroth order Bessel function plotted for comparison. The maximum T_{decay} measured here is 1.21 (60) ms at T_{mod}=24.12 μs. For comparison the bare spin qubit (T₂) and the dressed qubit are measured to be 16.1 (27)μs and 248 (39)μs in the same device [See FIGS. 18C and 18D]. The improvement in coherence time with distinct periods of the microwave field modulation, as apparent by the four peaks in FIG. 18A, agrees with the theoretical prediction originating from the geometric formalism.

Certain modulation frequencies are more desirable because they cancel out both first and second order noise, making the SMART qubit method more robust to detuning and microwave amplitude noise. From FIGS. 18A and 18B it can be seen how the optimal modulation period follows

T_{mod}^{opt}=jᵢ/Ω_{R}\sqrt{2},

where jᵢ is solution i to the zeroth order Bessel function. In this experiment, j₁=2.404826. The width of the four peaks in FIG. 18A demonstrates the robustness to modulation frequency fluctuations, or similarly, microwave amplitude fluctuations. Significant amplitude variations can be observed if the antenna is not broadband, for example if a microwave resonator is used to provide the driving field to the spin qubits 304. A 6 GHz resonator with a quality-factor of 10⁵ only has a 600 kHz bandwidth. In some embodiments, the resonator bandwidth is in the range of the modulation frequency (MHZ) to enable the SMART qubit methods. This can be relaxed by choosing a larger T_{mod} [peaks to the right in FIG. 18A] at the expense of longer gate times. Another alternative is to use multimode cavities.

### Experiment 2: Gate Calibration and Process Tomography.

As mentioned before for sinusoidally modulated global drive, a simple sinusoidal modulation of the Stark shift amplitude leads to a qubit control rotation axis that does not match either x or y. This means that in order to retrieve the traditional axes of rotation, it is necessary to combine multiple sinusoidal modulations in a combination that can be obtained from theory and calibrated directly using process tomography. Process tomography data is therefore acquired to confirm the rotation axes.

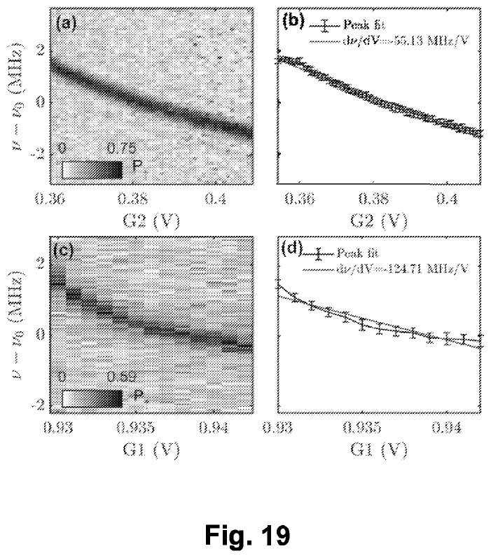

A typical Stark shift region for the SMART qubit technique is shown in FIGS. 19A and 19B where a Stark shift magnitude of −55 MHZ/V for gate G2 is measured. In FIGS. 19C and 19D Stark shift magnitude of −125 MHZ/V for gate G1 is measured. For gate G1, the Stark shift is observed to have a larger magnitude, but to be less linear. Therefore, gate G2 is used for gate control in these experiments.

To confirm the rotation axes previously predicted, process tomography is performed. In order to completely reconstruct the 2×2 density matrix, 6 tomography projections are acquired. From this experiment two variants of the SMART qubit method are demonstrated—i.e., a SMART qubit method with cosine modulation and a SMART qubit method with sine modulation. These variants are compared with dressed qubits.

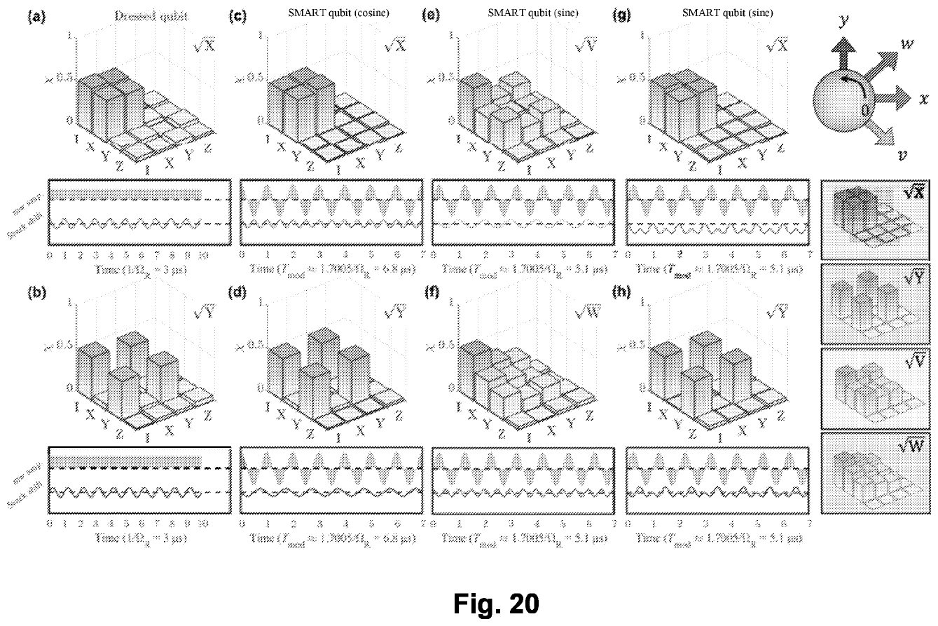

FIG. 20 shows the process tomography results for the gates \sqrt{X}, \sqrt{Y}, \sqrt{V} and \sqrt{W} for the dressed qubit using FM resonance control (in FIGS. 20A and 20B), for the cosine modulated SMART variant (in FIGS. 20C and 20D) and for the sine modulated SMART variant (in FIGS. 20E-20H). The height of the bars and the color code represent the absolute value of the superoperator matrix elements and complex phase information, respectively. The data is taken with 120 spin shots and ≤30 repeats. The \sqrt{V} and \sqrt{W} gates constitute rotations about an alternative, diagonal set of rotation axes (see top right insert), that can be used for the SMART qubit method. The individual panels contain the measured superoperator matrices as well as details on the pulse sequences and modulation shapes. For comparison, the ideal superoperators are plotted to the far right. All measured superoperator matrices are in agreement with the ideal matrices with good fidelity. In order for the comparison between the dressed and the SMART qubit method to be fair, the same global field root mean square power is used. For controlled rotations, Stark shift amplitudes are chosen such that the gate durations of the two qubits are approximately the same. Gate times for the SMART qubit are 7 x T_{mod} and the gate times for the dressed qubit is 10/52R, as shown in FIG. 20.

### Experiment 3: Oubit Performance by Randomized Benchmarking

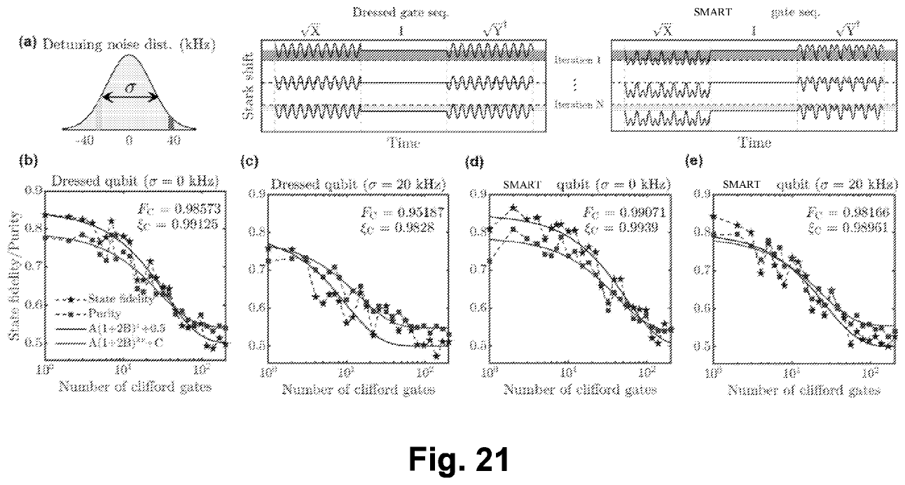

In order to assess the performance of the SMART qubit, randomized benchmarking is also performed. The average Clifford gate fidelity Fc and the noise coherence ξ_{c} are determined in this experiment according to the state purity. The Clifford gates are generated using the dressed basis gate set {X, Y, ±\sqrt{X}, ±\sqrt{Y}}. The results for the dressed qubit and SMART qubit are presented in FIG. 21. In particular, FIG. 21 shows single qubit randomized benchmarking with added detuning noise for robustness test. In FIG. 21A the noise implementation and the respective pulse sequences are shown. Randomized benchmarking data is shown for the dressed qubit in FIG. 21B with no added noise and in FIG. 21C with σ=20 KHz white, quasi-static Gaussian noise added on G2. The same is shown in FIGS. 21D and 21E for the sine modulated SMART qubit. The state fidelity data is fitted to A (1+2B)^{x}+1/2 and the noise coherence to A (1+2B)^{2x}+C. The data is taken with 120 spin shots and 20 different Clifford sequences for each sequence length. From these experiments, for the dressed scheme, the average Clifford gate fidelity and the noise coherence are found to be 98.6 (14) % and 99.1 (14) % without added noise, and 95.2 (48) % and 98.3 (48) % with added noise, respectively. For the SMART scheme gate fidelity and noise coherence are observed to be 99.1 (9) % and 99.4 (6) % without added noise and 98.2 (18) % and 99.0 (11) % with added noise.

Accordingly, it can be seen that the SMART qubit technique is more robust against detuning noise, dropping by less than 1% in both average Clifford gate fidelity and noise coherence. It is found that the Rabi frequency limits the gate speed of the SMART qubit technique, since one SMART gate lasts for at least one period of the modulation field (≥T_{mod} ≡1/Ω_{R}).

The duration of a SMART qubit technique gate compared to a square pulse conventional qubit gate is therefore necessarily longer.

### Experiment 4: More Advanced Modulation Strategies

As discussed, the additional parameter made available by the amplitude modulation is what allows cancelling higher order noise effects. Consequently, even more advanced modulation schemes can allow for increasingly higher orders of noise cancellation.

In this experiment, a modulation scheme that combines two modulation harmonics is tested. Specifically, the first and third harmonic are combined. The parameter θ is used to change the ratio of the two harmonics while keeping the power fixed.
Global modulation: cos (θ) cos (2πf_{mod}t)+sin (θ) cos (6πf_{mod}t)

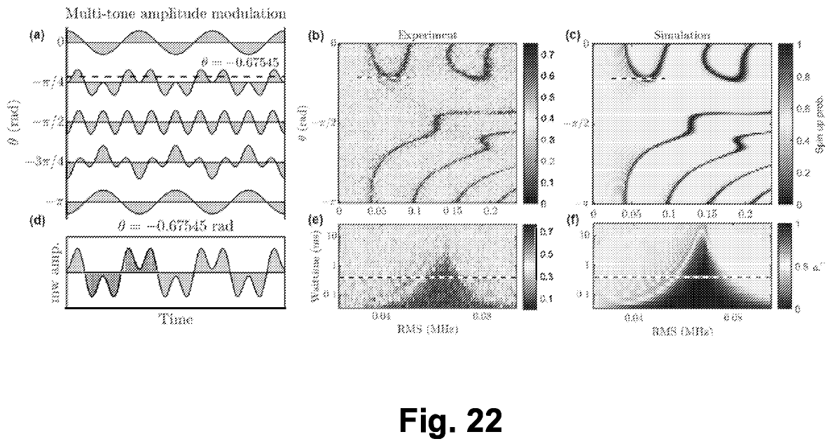

Examples of different modulation shapes used in this experiment are shown in FIG. 22A. In particular, FIG. 22A shows the different driving fields generated by combining the first and third harmonic of a sinusoid according to the above equation, where the modulated driving field is for θ=−0.67545 radians. FIG. 22B shows the experimental Ramsey data (100 shots, three repeats) where the wait time is fixed at 400 μs and T_{mod} equals 40 μs. The |↑ [symbol] probability is shown for different global field amplitudes (2R and ratios between the first and third harmonic represented by θ. FIG. 22D shows the |↑ [symbol] probability for different wait times and global amplitudes at θ=−0.67545 radians is indicated with a dashed line. The dashed line indicates the 400 μs wait time for which the data in FIG. 22C was taken. FIGS. 22C and 22F show the simulated data. The four peaks observed in FIG. 18 correspond to the case of θ=0 for which the relative amplitude of the third harmonic is zero. The high spin-up probability regions (T_{decay} >400 μs) in FIG. 22B indicate the more ideal modulation parameters for the multi-tone drive for which the SMART qubit method is less sensitive to amplitude fluctuations. These regions closely resemble the simulated data in FIG. 22C. One of these regions of high robustness is at θ=−0.67545 rad as indicated by the dashed lines in FIGS. 22B and 22C, and the corresponding modulation shape is shown in FIG. 22D. This special case is further investigated by recording Ramsey data for a range of amplitudes (see FIGS. 22E and 22F). The maximum T_{decay} in FIG. 22E is 2.15 ms. The width of the peak represents high resilience to amplitude fluctuations at the order of 10% of SR.

### Example Method for Dressed Qubits

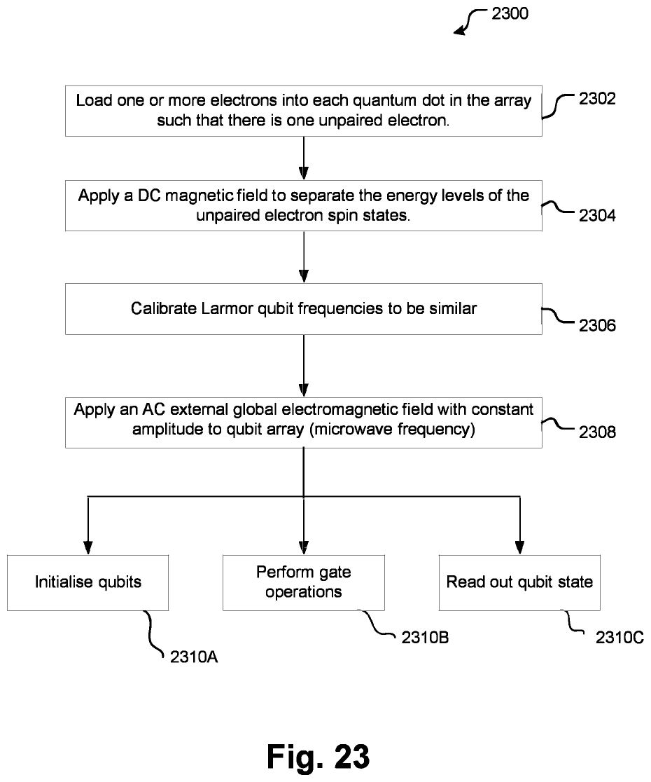

FIG. 23 shows a flowchart illustrating an example method 2300 using the dressed technique to perform an operation on a qubit array (e.g., qubits 304). In particular for each operation initialization, readout, single or two-qubit operations, steps 2302-2308 are performed.

The example method commences at step 2302, where one or more electrons are loaded into each of the quantum dots in the quantum dot array such that each quantum dot has at least one unpaired electron. In this example, a qubit is encoded in the spin of the unpaired electrons in each of the quantum dots.

Next, at step 2304, a DC magnetic field is applied to the qubit array 300 to separate the energy levels of the unpaired electron spin states. In one example, the DC magnetic field is applied by an external superconducting magnet. Further, the strength of the magnetic field may be 0.1-1.5 T.

Next, at step 2306, the Larmor frequencies are calibrated to be within a small bandwidth such that all qubits have a similar Larmor frequency. In one example, the Larmor frequencies are calibrated such that all the Larmor frequencies of the array of qubits are within a range of approximately 0-100 kHz from each other. As described previously, the Larmor frequency of a spin in a semiconductor device is determined by the microscopic environment that surrounds the spin. For the case of spin qubits in isotopically enriched silicon (²⁸Si), the spin-orbit interaction is the main mechanism that results in variable qubit Larmor frequencies. In one embodiment, a more purified ²⁸Si substrate may be utilized to minimize variations in Larmor frequencies between the various qubits caused by hyperfine coupling to residual ²⁹Si nuclei.

Next, at step 2308, an AC sinusoidal global electromagnetic field 302 with constant amplitude is applied to the qubits 304 in the qubit array. This causes the qubits 304 to become dressed by coupling the spin degree of freedom of the qubits 304 with the photons of the global electromagnetic field 302. The frequency of the global electromagnetic field 302 is chosen to match the bandwidth of Larmor frequencies, such that the qubits are on resonance with the global field 302. The global field 302 is always on and the qubits 304 in the qubit array are always being driven by the global field 302.

In some examples the global field 302 may be an AC magnetic field, and in other examples the global field 302 may be an AC electric field. In some examples the external global field 302 is a microwave frequency electromagnetic field.

After step 2308, the flowchart branches depending on the operation that needs to be performed on a qubit. That is, for initialization and readout the method 2300 proceeds to step 2310A, to perform a gate operation, the method 2300 proceeds to step 2310B, and for readout, the method 2300 proceeds to step 2310C. Importantly, the global field 302 is always on during each of initialization 2310A, gate operations 2310B, and readout 2310C.

For example, to initialize two qubits to perform a two-qubit gate operation, at step 2310A the detuning ∈ is ramped from positive to negative energy (see FIG. 5), while the qubit is still in resonance with the global magnetic field 302. Similarly, for readout of the dressed qubits, at step 2310C, the detuning ∈ is ramped from negative to positive energy (see FIG. 5), while the qubit is still in resonance with the global magnetic field.

To perform a qubit gate, at step 2310B, voltages may be applied to electrodes to control at least one qubit in the qubit array. For example, to perform a single-qubit gate using a given qubit voltages are applied to electrodes 306 surrounding that qubit using the frequency-shift keying method (FIG. 6A) or the FM resonance method (FIG. 6B). Two-qubit gates can also be performed at step 2310B in accordance with aspects of the present disclosure.

### Example Method for SMART Technique

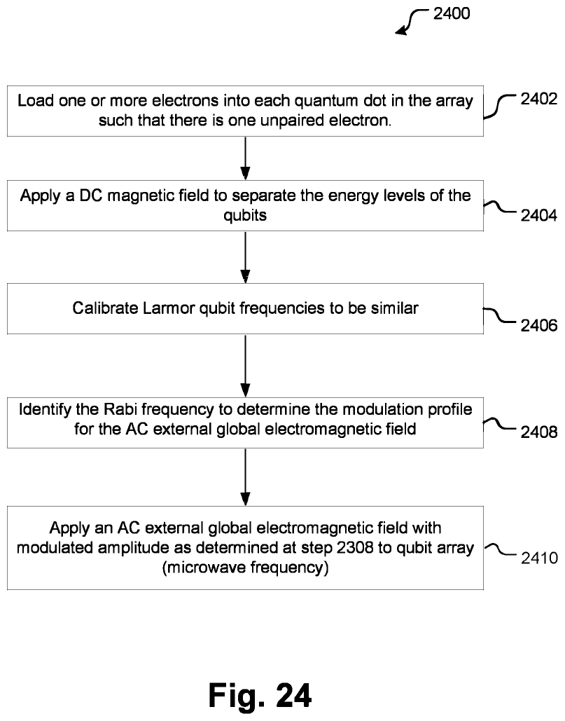

FIG. 24 shows a flowchart illustrating an example method 2400 using the SMART technique to dress qubits in the qubit array (e.g., qubits 304) with an oscillatory driving field that has a time-dependent amplitude.

The example method commences at step 2402, where one or more electrons are loaded into the qubit array. The example of the present disclosure focuses on spins in silicon quantum dots, but the mathematical model behind the SMART technique for qubit control can be applied to other qubit technologies, not only spins. Examples of technologies include but are not limited to superconducting qubits (phase, charge and transmon qubits), NV centers in diamond, ions in traps, neutral atoms, etc.

Next, at step 2404, a magnetic field is applied to the qubit array to separate the energy levels of the unpaired electron spin states.

At step 2406, the Larmor frequencies are calibrated to be within a small bandwidth, such that all qubits have a similar Larmor frequency. As the SMART technique is more robust to noise, it can handle grater variations in qubit Larmor frequencies than the dressed technique. In one example, the Larmor frequencies of the qubits in a qubit array under this technique can be in the range of 0-500 KHz. This eases the restrictions on the silicon substrate allowing for less pure ²⁸Si substrates to be used than allowable with the dressed technique.

Next, at step 2408, the Rabi frequency of the qubits is identified to determine the amplitude modulation profile for the AC external global electromagnetic field. By engineering the amplitude modulation frequency of the global field 302 to be in a certain proportion with the Rabi frequency, different types of noise can be cancelled. In particular, this calibrations step 2408 allows the global field 302 to be engineered in such a way that cancels out higher order noise and makes the dressed qubits more resilient to noise. The method 2400 can target multiple types of noise by adding different frequency and phase components to the amplitude modulation.

Next, at step 2410, an AC external global electromagnetic field with modulated amplitude is applied to the qubits 304 in the qubit array. In some example, the global field 302 is a sinusoidal modulation of amplitude that affects all qubits 304 in the qubit array concurrently. In other examples, the global field may be a cosinusoidal modulation of amplitude that affects all qubits 304 in the qubit array simultaneously. In general, the amplitude, frequency and phase modulated global field 302 determines the noise-cancelling properties.

It will be appreciated that although the prototype described above illustrates silicon metal-oxide-semiconductor (MOS) quantum dots, the presently disclosed systems and methods can be applied in Silicon-Germanium systems as well.

It will also be appreciated that although the described system leverages the intrinsic spin-orbit coupling created by the interface, the presently disclosed systems and methods can be applied in systems with an artificial spin-orbit field created by the inhomogeneous magnetic field of a magnetic material deposited nearby the quantum dot system.

It will also be appreciated that the microwave driving field described in the prototype affects the spins dominantly through its magnetic field component, but an AC electric field may also be applied globally or individually to all gates in order to obtain a similar resonant driving of all qubits, with the same dynamical decoupling effects.

Those skilled in the art will also appreciate that this system was described in the context of electron spins, but the same methods are applicable to quantum dots containing holes. It would also be applicable to other degrees of freedom of electrons and holes, such as charge, valley or composite spin states of multiple electrons or holes, such as spin singlets and triplets or hybrid spin-valley states.

It will also be recognized by those skilled in the art that the SMART protocol for qubit control can be applied to other qubit technologies, not only spins. Examples of technologies include but are not limited to superconducting qubits (phase, charge and transmon qubits), NV centers in diamond, ions in traps, neutral atoms, etc.

Further still, although the quantum processing systems described herein have been shown with gate electrodes for controlling corresponding qubits, these may not always be necessary. In other embodiments and examples other control means may be utilized without departing from the scope of the present disclosure.

The present embodiments are, therefore, to be considered in all respects as illustrative and not restrictive.

As used herein, except where the context requires otherwise, the term “comprise” and variations of the term, such as “comprising”, “comprises” and “comprised”, are not intended to exclude further additives, components, integers or steps.

1. A method for controlling one or more qubits in a quantum processing system, the quantum processing system comprising a plurality of qubits, the method comprising:
generating an AC electromagnetic field;
modulating the amplitude of the AC electromagnetic field to generate an amplitude modulated AC electromagnetic field;
applying the amplitude modulated AC electromagnetic field to the quantum processing system, wherein in an idle mode the plurality of qubits are tuned to be on resonance with the amplitude modulated AC electromagnetic field; and
individually controlling the Larmor frequency of the one or more qubits to change synchronously with the amplitude modulated AC electromagnetic field to perform an operation on the one or more qubits.

2. The method of claim 1 wherein the amplitude modulated AC electromagnetic field is applied globally to all qubits.

3. The method of claim 1 wherein the amplitude modulated AC electromagnetic field is applied locally to each qubit.

4. The method of claim 1, wherein the amplitude modulation frequency of the amplitude modulated AC electromagnetic field is engineered to be in a predefined proportion with the Rabi frequency of the plurality of qubits.

5. The method of any of the preceding claims, where the Larmor frequency of the plurality of qubits is set to be within a predefined threshold range.

6. The method of any of the preceding claims, where the Rabi frequency of the plurality of qubits is set to be within a predefined threshold range.

7. The method of claim 1, wherein the qubits are spin qubits in a semiconductor substrate.

8. The method of any of the preceding claims where the quantum processing system is a silicon-based system.

9. The method of claim 7, wherein the quantum processing system is a silicon MOS system.

10. The method of any one of the preceding claims, wherein the plurality of qubits are encoded in one or more electrons or holes confined in quantum dots.

11. The method of claim 7, where the Larmor frequency of the one or more qubits is controlled via a spin-orbit interaction.

12. The method of any one of claims 1 to 11, further comprising:
performing a single-qubit gate operation on a qubit of the one or more qubits by shifting the Larmor frequency of the qubit using a frequency modulated signal that has a frequency substantially matching the amplitude modulation frequency of the amplitude modulated AC electromagnetic field.

13. A method for controlling one or more qubits in a quantum processing system, the quantum processing system comprising a plurality of qubits, the method comprising:
applying an always on AC electromagnetic field to the quantum processing system, wherein in an idle mode the plurality of qubits are tuned to be on resonance with the AC electromagnetic field; and
performing an initialization, qubit gate, or readout operation on the one or more qubits by leveraging Pauli's exclusion principle while the AC electromagnetic field is applied to the quantum processing system.

14. The method of claim 13, further comprising, to perform qubit gate operations on the one or more qubits, individually controlling the Larmor frequency of the one or more qubits to bring the one or more qubits off resonance with the AC electromagnetic field.

15. The method of any of claims 13 to 14 wherein the AC electromagnetic field is an amplitude modulated AC electromagnetic field.

16. The method of any of claims 13 to 14, wherein the AC electromagnetic field has a constant amplitude.

17. The method of any one of claims 13 to 16 wherein the AC electromagnetic field is applied globally to all qubits.

18. The method of any one of claims 13 to 16 wherein the AC electromagnetic field is applied locally to each qubit.

19. The method of any one of claims 13 to 18, wherein the Larmor frequency of the plurality of qubits is set to be within a predefined threshold range.

20. The method of any one of claims 13 to 18, wherein the Rabi frequency of the plurality of qubits is set to be within a predefined threshold range.

21. The method of any one of claims 13 to 20, where the Larmor frequency of the one or more qubits is controlled via a spin-orbit interaction.

22. The method of any one of claims 13 to 21, further comprising:
performing a single-qubit gate operation on a qubit of the one or more qubits by modulating a detuning between the Larmor frequency of the qubit and the frequency of the AC electromagnetic field, wherein the detuning is modulated by shifting the Larmor frequency of the qubit sinusoidally at a frequency that matches the amplitude of the Rabi frequency of the qubit.

23. The method of any one of claims 13 to 22 claims, further comprising:
performing a two-qubit gate operation between two qubits of the one or more qubits by pulsing a voltage on a gate electrode between the two qubits or by detuning one qubit with respect to the other qubit, creating a controllable exchange coupling.

24. The method of any one of claims 13 to 23, wherein the qubits are spin qubits in a semiconductor substrate.

25. The method of any one of claims 13 to 24 where the quantum processing system is a silicon-based system.

26. The method of claim 25, wherein the quantum processing system is a silicon MOS system.

27. The method of any one of claims 13 to 26, wherein the plurality of qubits are encoded in quantum dots with one or more electrons or holes.
